(19) United States
(12) Patent Application Publication
(10) Pub. No.: US 2011/0156786 A1
(43) Pub. Date: Jun. 30, 2011

(54) FLIP-FLOP CIRCUIT AND FREQUENCY DIVIDING CIRCUIT

(75) Inventor: Satoshi Yamaguchi, Osaka (JP)

(73) Assignee: Panasonic Corporation, Osaka (JP)

(21) Appl. No.: 12/881,436

(22) Filed: Sep. 14, 2010

(30) Foreign Application Priority Data
Dec. 24, 2009 (JP) 2009-292629

(51) Int. Cl. H03K 3/289

(52) U.S. Cl. 327/203

(57) ABSTRACT

A flip-flop circuit has a function of respectively switching ON/OFF state of operation of a first data retaining circuit in a master side element and a second data retaining circuit in a slave side element, i.e., constituent elements of the flip-flop circuit, wherein the flip-flop circuit performs timing control, so as to reduce unnecessary current, eliminate the affect caused by parasitic capacitance. The flip-flop circuit operates with a low power consumption but has a high maximum operating frequency.

### BACKGROUND OF THE INVENTION

The present invention relates to a flip-flop circuit and a frequency dividing circuit using the flip-flop circuit serving as a constituent element of a radio communication semiconductor device used in a mobile communication apparatus and the like. More particularly, the present invention relates to a flip-flop circuit and a frequency dividing circuit having a circuit configuration that achieves low power consumption and high speed operation.

In the past, a flip-flop circuit used in a radio communication semiconductor device has a circuit configuration as shown in FIG. 25. FIG. 25 illustrates a conventional flip-flop circuit disclosed in Japanese Patent Laid-Open No. H5-347554.

The flip-flop circuit will be explained with reference to FIG. 25. In FIG. 25, reference numerals 102, 103, 210, 211 denote inverters, reference numeral 104, 108, 212, 214 denote PMOS transistors (hereinafter abbreviated as PMOS), reference numerals 105, 106, 107, 213, 215, 216 denote NMOS transistors (hereinafter abbreviated as NMOS). In FIG. 25, VDD denotes a high potential side power supply, VSS denotes a low potential side power supply, CK denotes a normal phase clock signal (hereinafter simply referred to as clock signal), CKB denotes a clock signal of reversed phase (hereinafter referred to as reversed phase clock signal), D denotes a normal phase data signal (hereinafter simply referred to as data signal), DB denotes a data signal of reversed phase (hereinafter referred to as reversed phase data signal), Q denotes a normal phase output signal (hereinafter simply referred to as output signal), and QB denotes an output signal of reversed phase (hereinafter referred to as reversed phase output signal). In the flip-flop circuit as shown in FIG. 25, a previous-stage circuit including inverters 102, 103, PMOS 104, 108, and NMOS 105, 106, 107 is a master side element 101, and a subsequent-stage circuit including inverters 210, 211, PMOS 212, 214, and NMOS 213, 215, 216 is a slave side element 201.

In the master side element 101 of the flip-flop circuit as shown in FIG. 25, an input end and an output end of the inverter 102 are interconnected with an output end and an input end of the inverter 103. Thus, the previous-stage flip-flop circuit is structured. The input end of the inverter 102 is connected to the high potential side power supply VDD via a PMOS 104 driven by the clock signal CK. Further, the input end of the inverter 102 is connected to the low potential side power supply VSS via the NMOS 105 connected with the PMOS 104 in series and the NMOS 106 driven by the reversed phase clock signal CKB.

On the other hand, the input end of the inverter 103 is connected to the high potential side power supply VDD via the PMOS 108 driven by the clock signal CK. Further, the input end of the inverter 103 is connected to the low potential side power supply VSS via the NMOS 107 connected with the PMOS 108 in series and the NMOS 106 driven by the reversed phase clock signal CKB.

In the slave side element 201 of the flip-flop circuit as shown in FIG. 25, an input end and an output end of the inverter 211 are interconnected with an output end and an input end of the inverter 210. Thus, the subsequent-stage flip-flop circuit is structured. The input end of the inverter 211 is connected to the high potential side power supply VDD via a PMOS 212 driven by the reversed phase clock signal CKB. Further, the input end of the inverter 211 is connected to the low potential side power supply VSS via the NMOS 213 connected with the PMOS 212 in series and the NMOS 216 driven by the clock signal CK.

On the other hand, the input end of the inverter 210 is connected to the high potential side power supply VDD via the PMOS 214 driven by the reversed phase clock signal CKB. Further, the input end of the inverter 210 is connected to the low potential side power supply VSS via the NMOS 215 connected with the PMOS 214 in series and the NMOS 216 driven by the clock signal CK.

The output end of the inverter 102 and the output end of the inverter 103, i.e., the output ends of the master side element 101, respectively connected to gate terminals of the NMOS 215 and the NMOS 213, i.e., the input ends of the slave side element 201.

In the flip-flop circuit shown in FIG. 25, an input terminal of a (normal phase) data signal D is the gate terminal of the NMOS 105, and an input terminal of a reversed phase data signal DB is the gate terminal of the NMOS 107. On the other hand, an output terminal of a (normal phase) output signal Q is the output end of the inverter 210, and an output terminal of the reversed phase output signal QB is the output end of the inverter 211.

In the conventional flip-flop circuit as shown in FIG. 25, each of the inverters 102, 103, 210, 211 has the same structure. FIGS. 26A and 26B illustrate a specific circuit configuration of the inverters 102, 103, 210, 211. FIG. 26A is a block diagram illustrating input/output relationship to the inverters 102, 103, 210, 211. FIG. 26B is a specific circuit configuration of the inverters 102, 103, 210, 211.

In FIG. 26A, IINV denotes an input end, OINV denotes an output end, VP denotes a power supply end, and VS denotes an earthing end. In the conventional flip-flop circuit as shown in FIG. 25, the power supply end VP of each of the inverters 102, 103, 210, 211 is connected to the high potential side power supply VDD, and the earthing end VS is connected to the low potential side power supply VSS.

In the circuit configuration as shown in FIG. 26B, a PMOS 31 and a NMOS 32 are arranged. The source terminal of the PMOS 31 is the power supply end VP, and the source terminal of the NMOS 32 is the earthing end VS. The gate terminal of the PMOS 31 and the gate terminal of the NMOS 32 are connected with each other to constitute the input end IINV, and the drain terminal of the PMOS 31 and the drain terminal of the NMOS 32 to constitute the output end OINV.

The operation of the conventional flip-flop circuit structured as described above will be explained with reference to FIG. 25 and FIG. 27. FIG. 27 is a timing chart illustrating the operation of the conventional flip-flop circuit as shown in FIG. 25.

A timing chart of FIG. 27 illustrates the (normal phase) data signal D, the reversed phase data signal DB, the (normal phase) clock signal CK, the reversed phase clock signal CKB, the output of the inverter 102, the output of the inverter 103, the (normal phase) output signal Q, the reversed phase output signal QB, the state of the operation (ON/OFF) of the master side element 101, and the state of the operation (ON/OFF) of the slave side element.

First, the operation will be explained when the clock signal CK is at L level.

When the clock signal is at L level, the reversed phase clock signal CKB is input to the gate terminal of the NMOS 106 of the master side element 101, and accordingly, the gate voltage thereof is at H level. The clock signal CK is input to the gate terminal of each of the PMOS 104 and the PMOS 108, and accordingly, the gate voltage thereof is at L level. Therefore, the master side element 101 is at ON state. It should be noted that the power supply ends VP of the inverters 102, 103 in the master side element 101 are always connected to the high potential side power supply VDD, and the earthing ends VS are always connected to the low potential side power supply VSS. Therefore, each of the inverters 102, 103 is always at ON state.

On the other hand, the clock signal CK is input to the gate terminal of the NMOS 216 of the slave side element 201, and accordingly, the gate voltage thereof is at L level. The reversed phase clock signal CKB is input to the gate terminal of each of the PMOS 212 and the PMOS 214, and accordingly, the gate voltage thereof is at H level. Therefore, the slave side element 201 is at OFF state. It should be noted that the power supply ends VP of the inverters 210, 211 in the slave side element 201 are always connected to the high potential side power supply VDD, and the earthing ends VS are always connected to the low potential side power supply VSS. Therefore, each of the inverters 210, 211 is always at ON state.

As described above, when the clock signal CK is at L level, the master side element 101 is at ON state. Therefore, the data signal D and the reversed phase data signal DE received from each of the input terminals are read, and the states of the data signal D and the reversed phase data signal DB are reflected in the outputs of the inverter 102 and the inverter 103. Regardless of timing of the clock signal CK and the reversed phase clock signal CKB, the inverters 102, 103 of the master side element 101 are always at ON state, and the inverter 102 and the inverter 103 retain the changed levels.

At this occasion, the slave side element 201 is at OFF state but the inverter 210 and the inverter 211 of the slave side element 201 are always at ON state. Accordingly, the slave side element 201 retains and outputs the output signal Q and the reversed phase output signal QB output by the slave side element 201 at a previous time in which the clock signal CK was at H level.

As shown in FIG. 27, the data signal D was at L level before a time A of the clock signal CK (rise), but is at H level after a time B (fall). Therefore, at the time B, the master side element 101 changes the output of the inverter 102 to H level, and changes the output of the inverter 103 to L level.

Subsequently, the operation will be explained when the clock signal CK is at H level.

When the clock signal CK is at H level, the reversed phase clock signal CKB is input to the gate terminal of the NMOS 106 of the master side element 101, and accordingly, the gate voltage thereof is at L level. The clock signal CK is input to the gate terminal of each of the PMOS 104 and the PMOS 108, and accordingly, the gate voltage thereof is at H level. Therefore, the master side element 101 is at OFF state. It should be noted that the inverters 102, 103 in the master side element 101 are always at ON state as described above.

On the other hand, the clock signal CK is input to the gate terminal of the NMOS 216 of the slave side element 201, and accordingly, the gate voltage thereof is at H level. The reversed phase clock signal CKB is input to the gate terminal of each of the PMOS 212 and the PMOS 214, and accordingly, the gate voltage thereof is at L level. Therefore, the slave side element 201 is at ON state. It should be noted that the inverters 210, 211 in the slave side element 201 are always at ON state.

The slave side element 201 is at ON state. Therefore, the output signals of the inverter 102 and the inverter 103 are read, and are reflected in the output signal Q and the reversed phase output signal QB of the slave side element 201. Regardless of timing of the clock signal CK and the reversed phase clock signal CKB, the inverters 210, 211 of the slave side element 201 are always at ON state, and the output signal Q and the reversed phase output signal QB are retained at the changed levels.

As shown in FIG. 27, the output of the inverter 102 was at L level before the time A of the clock signal CK (rise), and at H level after the time B (fall). Therefore, at a time C (rise) which is the time subsequent to the time B, the slave side element 201 changes the output signal Q to H level, and changes the reversed phase output signal QB to L level. Accordingly, regardless of timing of the clock signal CK and the reversed phase clock signal CKB, the inverters 210, 211 of the slave side element 201 are always at ON state, and the output signal Q and the reversed phase output signal QB are retained at the changed levels, as described above.

According to the above-described operation, the flip-flop circuit is achieved.

Constituent elements, i.e., the master side element 101 and the slave side element 201, in the conventional flip-flop circuit shown in FIG. 25 are configured to be switched between ON/OFF states by the clock signal CK and the reversed phase clock signal CKB. However, the inverters 102, 103, 210, 211 in the master side element 101 and the slave side element 201 are always at ON state regardless of timing of the clock signal CK and the reversed phase clock signal CKB.

Another conventional techniques are disclosed in Japanese Patent Laid-Open No. H4-258012 and Kenji TANIGUCHI, Introduction to CMOS Analog Circuit, Fourth Edition, CQ Publishing Co., Ltd., Aug. 1, 2006, pp. 33 to 36.

As described above, in the conventional flip-flop circuit, the inverters 102, 103 of the master side element 101 and the inverters 210, 211 of the slave side element 201 are always at ON state. Therefore, when the inverters 102, 103, 210, 211 are not substantially operating, the inverters 102, 103, 210, 211 are at ON state, which causes a problem in that unnecessary currents are consumed. In addition, there is a problem in that the operating speed is slow due to the always ON states of the inverters 102, 103, 210, 211.

In the conventional flip-flop circuit, the inverters 102, 103 having data retaining function in the master side element 101 and the inverter 210, 211 having data retaining function in the slave side element 201 are always at ON state. Therefore, when the data signal D and the reversed phase data signal DB change from L level to H level or change oppositely, the inverters 102, 103, 210, 211 consumes electric currents.

Further, there is a problem in that a parasitic capacitance between the gate and the source of each inverter serves a load of the circuit constituted by PMOS, NMOS in a stage previous thereto, and reduces the operating speed and the maximum operating frequency.

The present invention aims to solve various kinds of problems in the above-described conventional flip-flop circuit. It is an object of the present invention to provide a flip-flop circuit configured to switch ON/OFF operational state of a circuit having a data retaining function, i.e., a constituent element of a flip-flop circuit, and the flip flop circuit achieves low power consumption and high speed operation.

### SUMMARY OF THE INVENTION

In the below summary, reference numerals and the like used in the below-explained embodiments indicated shown in parentheses, in order to show relationship with the below-explained embodiments and to allow easy understanding of the invention. However, these reference numerals do not limit the present invention to the below-explained embodiments. The present invention includes various kinds of elements representing the same functions and configurations as the functions and configurations described in the below-explained embodiments.

A flip-flop circuit according to a first aspect of the present invention includes a master side element (100) including a first data reading circuit (17) and a first data retaining circuit (18) and a slave side element (200) including a second data reading circuit (19, 19A) and a second data retaining circuit (20), wherein power supplies of the first data retaining circuit (18) and the second data reading circuit (19, 19A) are controlled by a normal phase clock signal (CK) input from an outside, and power supplies of the first data reading circuit (17) and the second data retaining circuit (20) are controlled by a reversed phase clock signal (CKB) having a phase opposite to the normal phase clock signal. The flip-flop circuit according to the first aspect thus configured can switch ON/OFF state of operation of circuits having data retaining function. The flip-flop circuit consumes low power and improves the maximum operating frequency.

A flip-flop circuit according to a second aspect of the present invention is based on the first aspect, wherein the first data reading circuit (17) and the second data reading circuit (19) includes differential circuits, and wherein the first data retaining circuit (18) and the second data retaining circuit (20) include inverter circuits.

A flip-flop circuit according to a third aspect of the present invention is based on the first aspect, wherein the first data reading circuit (17) includes a differential circuit, and wherein the first data retaining circuit (18), the second data reading circuit (19A), and the second data retaining circuit (20) include inverter circuits.

A flip-flop circuit according to a fourth aspect of the present invention is based on the first to third aspects, wherein the first data retaining circuit (18) includes a first NMOS (1), and an input end and an output end of a first inverter (2) are interconnected with an output end and an input end of a second inverter (3), wherein an earthing end of the first inverter (1) and the second inverter (3) is connected to a low potential side power supply (VSS) via the first NMOS (1), and wherein a power supply end of the first inverter and the second inverter is connected to a high potential side power supply (VDD).

A flip-flop circuit according to a fifth aspect of the present invention is based on the fourth aspect, wherein the first data reading circuit (17) includes a first PMOS (4), a second PMOS (8), a second NMOS (5), a third NMOS (6), and a fourth NMOS (7), wherein an input end of the first inverter (2) in the first data retaining circuit is connected to the high potential side power supply (VDD) via the first PMOS (4), and is connected to the low potential side power supply (VSS) via the second NMOS (5) and the third NMOS (6), and wherein an input end of the second inverter (3) in the first data retaining circuit (18) is connected to the high potential side power supply (VDD) via the second PMOS (8), and is connected to the low potential side power supply (VSS) via the fourth NMOS (7) and the third NMOS (6).

A flip-flop circuit according to a sixth aspect of the present invention is based on the fifth aspect, wherein the second data retaining circuit (20) includes a fifth NMOS (9), and an input end and an output end of a third inverter (10) are interconnected with an output end and an input end of a fourth inverter (11), wherein an earthing end of the third inverter (10) and the fourth inverter (11) is connected to a low potential side power supply (VSS) via the fifth NMOS (9), and wherein a power supply end of each of the third inverter (10) and the fourth inverter (11) is connected to the high potential side power supply (VDD).

A flip-flop circuit according to a seventh aspect of the present invention is based on the sixth aspect, wherein the second data reading circuit (19) includes a third PMOS (12), a fourth PMOS (14), a sixth NMOS (13), a seventh NMOS (16), and a eighth NMOS (15), wherein an input end of the third inverter (10) in the second data retaining circuit (20) is connected to the high potential side power supply (VDD) via the fourth PMOS (14), and is connected to the low potential side power supply (VSS) via the eighth NMOS (15) and the seventh NMOS (16), wherein an input end of the fourth inverter (11) in the second data retaining circuit (20) is connected to the high potential side power supply (VDD) via the third PMOS (12), and is connected to the low potential side power supply (VSS) via the sixth NMOS (13) and the seventh NMOS (16), wherein an output end of the first inverter (2), i.e., one of output ends of the master side element, is connected to a gate terminal of the eighth NMOS (15), i.e., one of input ends of the slave side element, and wherein an output end of the second inverter (3), i.e., the other of output ends of the master side element, is connected to a gate terminal of the sixth NMOS (13), i.e., the other of input ends of the slave side element.

A flip-flop circuit according to an eighth aspect of the present invention is based on the sixth aspect, wherein the second data reading circuit (19A) includes a fifth inverter (21), a sixth inverter (22), and a seventh NMOS (16), wherein an input end of the third inverter (10) in the second data retaining circuit (20) is connected to an output end of the fifth inverter (21), and an input end of the fourth inverter (11) in the second data retaining circuit is connected to an output end of the sixth inverter (22), and wherein an earthing end of each of the fifth inverter (21) and the sixth inverter (22) is connected to the low potential side power supply (VSS) via the seventh NMOS (16), and a power supply end of the fifth inverter (21) and the sixth inverter (22) is connected to the high potential side power supply (VDD).

A flip-flop circuit according to a ninth aspect of the present invention is based on the seventh aspect, wherein the normal phase clock signal (CK) is input to a gate terminal of each of the first PMOS (4), the second PMOS (8), the first NMOS (1), and the seventh NMOS (16), and a reversed phase clock signal (CKB) having a phase opposite to the normal phase clock signal is input to a gate terminal of each of the third MOS (12), the fourth PMOS (14), the third NMOS (6), and the fifth NMOS (9).

A flip-flop circuit according to a tenth aspect of the present invention is based on the eighth aspect, wherein the normal phase clock signal (CK) is input to a gate terminal of each of the first PMOS (4), the second PMOS (8), the first NMOS (1), and the seventh NMOS (16), and a reversed phase clock signal (CKB) having a phase opposite to the normal phase clock signal is input to a gate terminal of each of the third NMOS (6) and the fifth NMOS (9).

A flip-flop circuit according to an eleventh aspect of the present invention is based on the ninth or tenth aspects, wherein the input terminal for inputting the normal phase data signal (D) is the gate terminal of the second NMOS (5), and the input terminal for inputting the reversed phase data signal having a phase opposite to the normal phase data signal is the gate terminal of the fourth NMOS (7), and wherein in the output terminal of the flip-flop circuit, an output end of the third inverter (10) is a normal phase output signal terminal for outputting the normal phase output signal, and an output end of the fourth inverter (11) is a reversed phase output terminal for outputting the reversed phase output signal having a phase opposite to the normal phase output signal.

A flip-flop circuit according to a twelfth aspect of the present invention is based on the ninth or tenth aspects, wherein the master side element and the slave side element further including reset devices (300A to 300D), wherein the reset devices (300A to 300D) includes: a first reset circuit (PMOS 23) arranged between the high potential side power supply (VDD) and the output end of the second inverter (3), i.e., the output end of the master side element; a second reset circuit (NMOS 24) in which a drain terminal and a source terminal of the first NMOS (1) are respectively connected to a drain terminal and a source terminal of the second reset circuit (NMOS 24) in first data retaining circuit (18); a third reset circuit (NMOS 25) in which a drain terminal and a source terminal of the seventh NMOS (16) are respectively connected to a drain terminal and a source terminal of the third reset circuit (NMOS 25) in second retaining circuit (20); and a fourth reset circuit (PMOS 26) arranged between the high potential side power supply (VDD) and an output end of the fourth inverter (1), i.e., an output signal terminal of the reversed phase of the flip-flop circuit, wherein the normal phase reset signal (R) is input to a control terminal of each of the second reset circuit (NMOS 24) and the third reset circuit (NMOS 25), and the reversed phase reset signal (RB) having a phase opposite to the normal phase reset signal is input to a control terminal of each of the first reset circuit (PMOS 23) and the fourth reset circuit (PMOS 26).

A flip-flop circuit according to a thirteenth aspect of the present invention is based on the ninth or tenth aspects, wherein the first data reading circuit (17) and the first data retaining circuit (18) in the master side element and the second data reading circuit (19, 19A) and the second data retaining circuit (20) in the slave side element further include power-down devices (400A to 400D) for inputting a power-down signal PD for turning off a power supply, wherein the power-down devices includes: a first power-down circuit (PMOS 27) arranged between the high potential side power supply and a source of each of the first PMOS (4) and the second PMOS (8) of the first data reading circuit (17) in the master side element; a second power-down circuit (PMOS 28) arranged between the high potential side power supply and a power supply end of the first inverter (2) and the second inverter (3) of first data retaining circuit (18) in the master side element; a third power-down circuit (PMOS 29) arranged between the high potential side power supply and a source of each of the third PMOS (12) and the fourth PMOS (14) of the second data reading circuit (19) in the slave side element; and a fourth power-down circuit (PMOS 30) arranged between the high potential side power supply and a power supply end of the third inverter (10) and the fourth inverter (11) of second data retaining circuit (20) in the slave side element, and wherein the power-down signal for turning off a power supply is configured to input to a control terminal of each of the first power-down circuit (PMOS 27), the second power-down circuit (PMOS 28), the third power-down circuit (PMOS 29), and the fourth power-down circuit (PMOS 30).

A flip-flop circuit according to a fourteenth aspect of the present invention includes a master side element (100) including a first data reading circuit (17) and a first data retaining circuit (18A) and a slave side element (200) including a second data reading circuit (19A) and a second data retaining circuit (20A), wherein a power supply of the second data reading circuit (19A) is controlled by a normal phase clock signal (CK) input from an outside, and a power supply of the first data reading circuit (17) is controlled by a reversed phase clock signal (CKB) having a phase opposite to the normal phase clock signal, wherein the first data reading circuit (17) includes a differential circuit, and wherein the first data retaining circuit (18A), the second data reading circuit (19A), and the second data retaining circuit (20A) include inverter circuits. In the flip-flop circuit according to the fourteenth aspect thus configured, the second data reading circuit in the slave side element is constituted by an inverter circuit. Therefore, the flip-flop circuit consumes low power and improves the maximum operating frequency.

A flip-flop circuit according to a fifteenth aspect of the present invention is based on the fourteenth aspect, wherein the second data retaining circuit (20A) is configured such that an input end and an output end of a third inverter (10) are interconnected with an output end and an input end of a fourth inverter (11), wherein an earthing end of the third inverter (10) and the fourth inverter (11) is connected to a low potential side power supply (VSS), and wherein a power supply end of the third inverter (10) and the fourth inverter (11) is connected to a high potential side power supply (VDD).

A flip-flop circuit according to a sixteenth aspect of the present invention is based on the fifteenth aspect, wherein the second data reading circuit (19A) includes a fifth inverter (21), a sixth inverter (22), and a seventh NMOS (16), wherein an input end of the third inverter (10) in the second data retaining circuit (20A) is connected to an output end of the fifth inverter (21), and an input end of the fourth inverter (11) in the second data retaining circuit (20A) is connected to an output end of the sixth inverter (22), and wherein an earthing end of each of the fifth inverter (21) and the sixth inverter (22) is connected to the low potential side power supply (VSS) via the seventh NMOS (16), and a power supply end of each of the fifth inverter (21) and the sixth inverter (22) is connected to the high potential side power supply (VDD).

A frequency dividing circuit according to a seventeenth aspect of the present includes a logical circuit and the flip-flop circuit according to any one of the first to sixteenth aspects. A dividing ratio may be controlled by a dividing switching signal (M). The frequency dividing circuit thus configured achieves a great effect of being able to perform operation at a fast speed with a low power consumption at a desired dividing ratio.

In the present invention, ON/OFF state of a circuit having a data retaining function, i.e., a constituent element of the flip-flop circuit, can be switched, and the circuit is configured to be in ON state only when the function is performed. Therefore, the flip-flop circuit consuming low power and capable of performing operation at a fast speed can be provided.

### BRIEF DESCRIPTION OF THE DRAWINGS

The present invention will become more fully understood from the detailed description and the accompanying drawings, wherein:

FIG. 1 is a block diagram illustrating a configuration of a flip-flop circuit according to the first embodiment of the present invention;

FIG. 2 is a circuit diagram illustrating a flip-flop according to the first embodiment;

FIG. 3 is a timing chart illustrating operation of each unit of the flip-flop circuit according to the first embodiment;

FIG. 4A is diagram illustrating a parasitic capacitance of an inverter in a conventional flip-flop circuit;

FIG. 4B is diagram illustrating a parasitic capacitance of an inverter in a conventional flip-flop circuit;

FIG. 5A is circuit diagram illustrating a parasitic capacitance of an inverter in the flip-flop circuit according to the first embodiment;

FIG. 5B is circuit diagram illustrating a parasitic capacitance of an inverter in the flip-flop circuit according to the first embodiment;

FIG. 6 is a diagram for comparing consumed currents in a flip-flop circuit according to the first and second embodiments of the present invention and the conventional flip-flop circuit;

FIG. 7 is a diagram for comparing maximum operating frequencies in the flip-flop circuit according to the first and second embodiments of the present invention and the conventional flip-flop circuit;

FIG. 8 is a circuit diagram illustrating a flip-flop circuit according to the second embodiment of the present invention;

FIG. 9 is a diagram for comparing input/output characteristics of the conventional flip-flop circuit and the flip-flop circuit according to the second embodiment;

FIG. 10 is a circuit diagram illustrating a flip-flop circuit according to the third embodiment of the present invention;

FIG. 11 is a timing chart illustrating operation of each unit of the flip-flop circuit according to the third embodiment;

FIG. 12 is a circuit diagram illustrating a configuration of a flip-flop circuit according to the fourth embodiment of the present invention;

FIG. 13 is a circuit diagram illustrating a configuration of a flip-flop circuit according to the fifth embodiment of the present invention;

FIG. 14 is a circuit diagram illustrating a configuration of a flip-flop circuit according to the sixth embodiment of the present invention;

FIG. 15 is a circuit diagram illustrating a configuration of a flip-flop circuit according to the seventh embodiment of the present invention;

FIG. 16 is a block diagram illustrating a configuration of a one-quarter/one-fifth variable frequency dividing circuit according to the eighth embodiment of the present invention;

FIG. 17 is a circuit diagram illustrating specific configurations of logical circuits NOR used in the one-quarter/one-fifth variable frequency dividing circuit according to the eighth embodiment and a one-half/one-third variable frequency dividing circuit according to the ninth embodiment;

FIG. 18 is a timing chart illustrating operation of each unit during one-quarter dividing operation of the one-quarter/one-fifth variable frequency dividing circuit according to the eighth embodiment;

FIG. 19 is a timing chart illustrating operation of each unit during one-fifth operation of the one-quarter/one-fifth variable frequency dividing circuit according to the eighth embodiment;

FIG. 20 is a circuit diagram illustrating a specific configuration of a flip-flop circuit having an NOR function used in the one-quarter/one-fifth variable frequency dividing circuit according to the eighth embodiment;

FIG. 21 is a circuit diagram illustrating another specific configuration of a flip-flop circuit having an NOR function used in the one-quarter/one-fifth variable frequency dividing circuit according to the eighth embodiment;

FIG. 22 is a block diagram illustrating a configuration of the one-half/one-third variable frequency dividing circuit according to the ninth embodiment of the present invention;

FIG. 23 is a timing chart illustrating operation of each unit during one-half operation of the one-half/one-third variable frequency dividing circuit according to the ninth embodiment;

FIG. 24 is a timing chart illustrating operation of each unit during one-third operation of the one-half/one-third variable frequency dividing circuit according to the ninth embodiment;

FIG. 25 is a circuit diagram illustrating a configuration of the conventional flip-flop circuit;

FIG. 26A is figure illustrating a configuration of an inverter circuit;

FIG. 26B is figure illustrating a configuration of an inverter circuit; and

FIG. 27 is a timing chart illustrating operation of each unit in the conventional flip-flop circuit.

### DESCRIPTION OF THE PREFERRED EMBODIMENTS

Preferred embodiments of a flip-flop circuit according to the present invention will be hereinafter explained with reference to the attached drawings. In the explanations about the following embodiments, constituent elements attached with the same reference numerals represent substantially the same functions, configurations, and operations, and the redundant explanation thereabout may be omitted. It is to be understood that the explanations about the embodiments are shown as examples, and the present invention includes similar flip-flop circuits based on similar technical concepts and frequency dividing circuits using the flip-flop circuits.

### First Embodiment

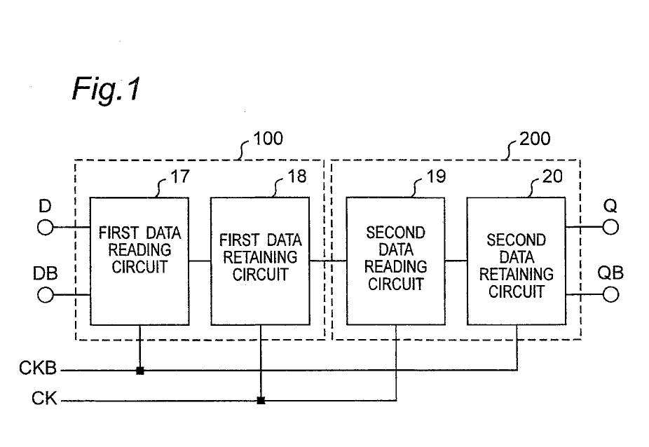

FIG. 1 is a block diagram illustrating a configuration of a flip-flop circuit according to the first embodiment of the present invention. As shown in FIG. 1, the flip-flop circuit according to the first embodiment includes a master side element 100 and a slave side element 200. The master side element 100 includes a first data reading circuit 17 and a first data retaining circuit 18, and the slave side element 200 includes a second data reading circuit 19 and a second data retaining circuit 20.

In the master side element 100, the first data reading circuit 17 receives a data signal D and a reversed phase data signal, and the first data retaining circuit 18 has a function of retaining the data signal and the reversed phase data signal read by the first data reading circuit 17.

On the other hand, in the slave side element 200, the second data reading circuit 19 reads the data signal and the reversed phase data signal retained in the first data retaining circuit 18 of the master side element 100. The second data retaining circuit 20 has a function of retaining the data signal and the reversed phase data signal read by the second data reading circuit 19, and outputs the data signal and the reversed phase data signal.

According to the flip-flop circuit according to the first embodiment, the first data reading circuit 17 and the second data reading circuit 19 are formed of differential circuits, and the first data retaining circuit 18 and the second data retaining circuit 2a are formed of inverter circuits. Further, drive power supplies of the first data retaining circuit 18 and the second data reading circuit 19 are controlled by a clock signal given from the outside. Drive power supplies of the first data reading circuit 17 and the second data retaining circuit 20 are controlled by a reversed phase clock signal having a phase opposite to the clock signal. Thus, the operation of the flip-flop circuit is achieved.

The flip-flop circuit according to the first embodiment having the structure as described above performs the following operation. When the first data reading circuit 17 of the master side element 100 is in ON state, the first data retaining circuit 18 of the master side element 100 is in OFF state. When the second data reading circuit 19 of the slave side element 200 is in ON state, the second data retaining circuit 20 of the slave side element 200 is in OFF state.

By performing the above operation, the flip-flop circuit according to the first embodiment achieves an effect of reducing the consumption currents flowing through the inverter circuits, i.e., constituent elements of the first and second data retaining circuits 18, 20, when the outputs of the first and data reading circuits 17, 19 change from L level to H level or change oppositely.

The configuration and operation of the flip-flop circuit according to the first embodiment will be hereinafter explained specifically in more detail.

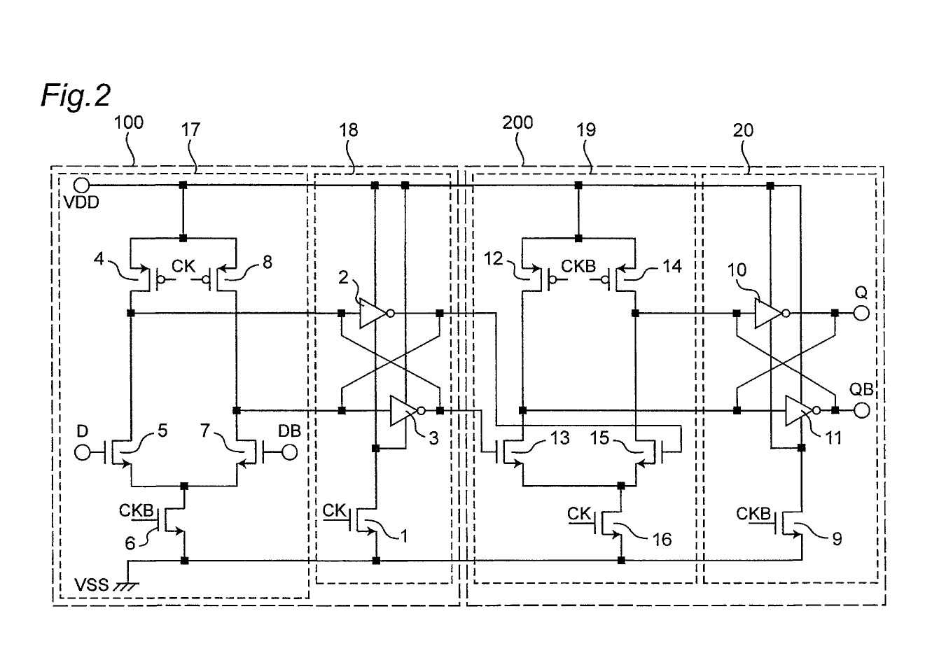

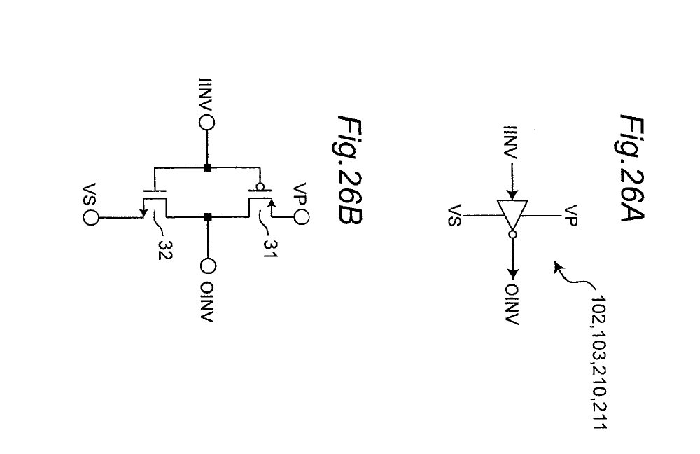

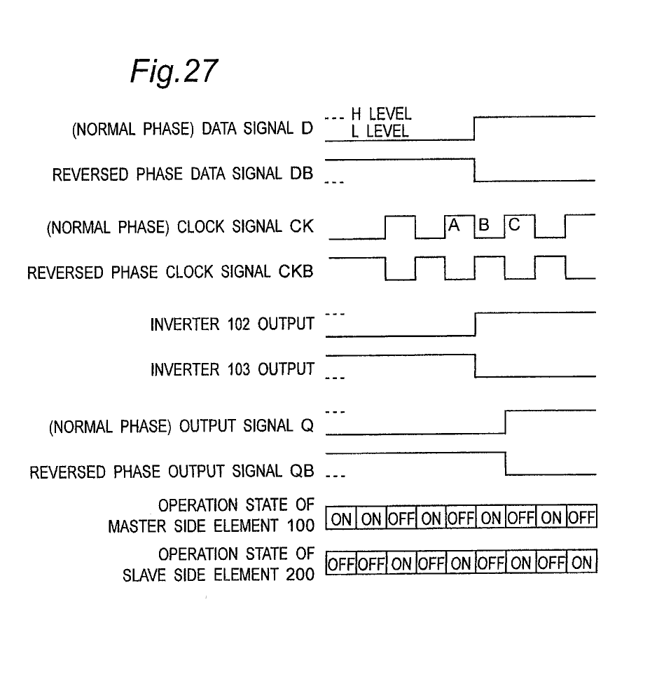

FIG. 2 is a circuit diagram illustrating a specific configuration of the flip-flop circuit according to the first embodiment. In FIG. 2, reference numerals 2, 3, 10, 11 denote inverters, reference numerals 4, 8, 12, 14 denote PMOS transistors (hereinafter abbreviated as a PMOS), and reference numerals 1, 5, 6, 7, 9, 13, 15, 16 denote NMOS transistors (hereinafter abbreviated as NMOS). In the flip-flop circuit according to the first embodiment, each of the inverters 2, 3, 10, 11 has the same structure. For example, each of the inverters 2, 3, 10, 11 may have the same circuit configuration as the above-explained inverter shown in FIG. 26B.

In FIG. 2, VDD denotes a high potential side power supply VSS denotes a low potential side power supply. CK denotes a normal phase clock signal (hereinafter simply referred to as clock signal). CKB denotes a reversed phase clock signal (hereinafter referred to as reversed phase clock signal). D denotes a normal phase data signal (hereinafter simply referred to as data signal). DB denotes a reversed phase data signal (hereinafter referred to as reversed phase data signal). Q denotes a normal phase output signal (hereinafter simply referred to as output signal). QB denotes an output signal of reversed phase (hereinafter referred to as reversed phase output signal). In the flip-flop circuit according to the first embodiment as shown in FIG. 2, a previous-stage circuit including the inverters 2, 3, the PMOS 4, 8, and NMOS 5, 6, 7 is the master side element 100, and a subsequent-stage circuit including the inverters 10, 11, PMOS 12, 14, and NMOS 13, 15, 16 is the slave side element 200.

As shown in FIG. 2, in the master side element 100, the first data reading circuit 17 receiving the data signal D and the reversed phase data signal DB includes the PMOS 4, 8, and the NMOS 5, 6, 7. In the master side element 100, the first data retaining circuit 18 having the data retaining function includes the inverters 2, 3 and the NMOS 1.

On the other hand, in the slave side element 200, the second data reading circuit 19 reading data retained in the master side element 100 includes the PMOS 12, 14 and the NMOS 13, 15, 16. In the slave side element 200, the second data retaining circuit 20 including data retaining function and outputting data includes the inverters 10, 11 and the NMOS 9.

In the first data retaining circuit 18 of the master side element 100 of the flip-flop circuit according to the first embodiment, the input end and the output end of the inverter 2 are interconnected with the output end and the input end of the inverter 3. The input end of the inverter 2 is connected to the high potential side power supply VDD via the PMOS 4 driven by the clock signal CK in the first data reading circuit 17. The input end of the inverter 2 is connected to the low potential side power supply VSS via the NMOS 5 connected with the PMOS 4 in series and the NMOS 6 driven by the reversed phase clock signal CKB in the first data reading circuit 17.

On the other hand, the input end of the inverter 3 is connected to the high potential side power supply VDD via the PMOS 8 driven by the clock signal CK in the first data reading circuit 17. Further, the input end of the inverter 3 is connected to the low potential side power supply VSS via the NMOS 7 connected with the PMOS 8 in series and the NMOS 6 driven by the reversed phase clock signal CKB in the first data reading circuit 17.

The first data retaining circuit 18 is arranged with the NMOS 1. The earthing end VS of each of the inverters 2, 3 (see FIG. 26A) is connected to the low potential side power supply VSS via the NMOS 1. The power supply end VP of each of the inverters 2, 3 (see FIG. 26A) is connected to the high potential side power supply VDD.

In the second data retaining circuit 20 of the slave side element 200 of the flip-flop circuit according to the first embodiment, the input end and the output end of the inverter 11 are interconnected with the output end and the input end of the inverter 10. The input end of the inverter 11 is connected to the high potential side power supply VDD via the PMOS 12 driven by the reversed phase clock signal CKB in the second data reading circuit 19. Further, the input end of the inverter 11 is connected to the low potential side power supply VSS via the NMOS 13 connected with the PMOS 12 in series and the NMOS 16 driven by the clock signal CK in the second data reading circuit 19.

On the other hand, the input end of the inverter 10 is connected to the high potential side power supply VDD via the PMOS 14 driven by the reversed phase clock signal CKB in the second data reading circuit 19. Further, the input end of the inverter 10 is connected to the low potential side power supply VSS via the NMOS 15 connected with the PMOS 14 in series and the NMOS 16 driven by the clock signal CK in the second data reading circuit 19.

The output end of the inverter 2 and the output end of the inverter 3, i.e., the output end of the master side element 100, respectively connected to gate terminals of the NMOS 15 and the NMOS 13, i.e., the input ends of the slave side element 201.

In the flip-flop circuit according to the first embodiment, an input terminal of a (normal phase) data signal D is the gate terminal of the NMOS 5 in the first data reading circuit 17, and an input terminal of a reversed phase data signal DB is the gate terminal of the NMOS 7 in the first data reading circuit 17. On the other hand, an output terminal of a (normal phase) output signal Q is the output end of the inverter 10 in the second data retaining circuit 20, and an output terminal of the reversed phase output signal QB is the output end of the inverter 11 in the second data retaining circuit 20.

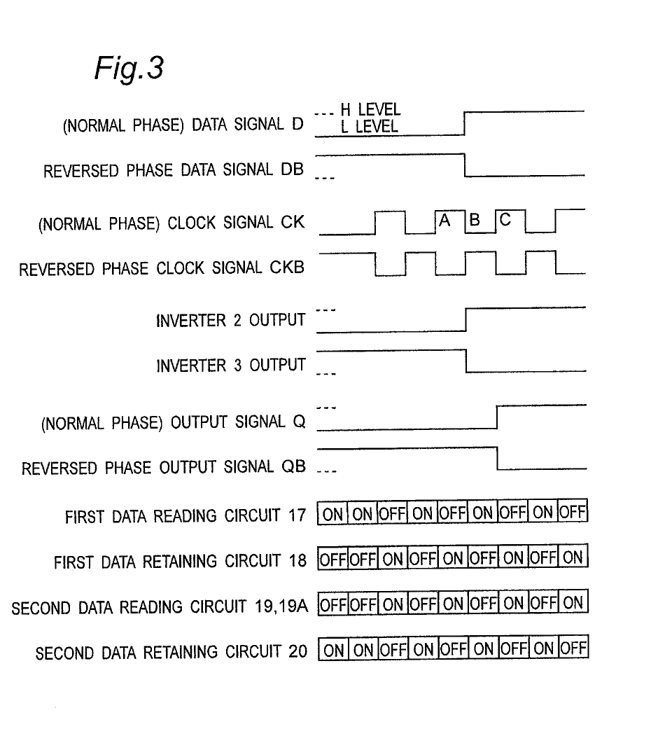

The operation of the flip-flop circuit according to the first embodiment having the above configuration will be explained with reference to FIG. 2 and FIG. 3. FIG. 3 is a timing chart illustrating operation of the flip-flop circuit according to the first embodiment as shown in FIG. 2.

The timing chart of FIG. 3 illustrates the (normal phase) data signal D, the reversed phase data signal DB, the (normal phase) clock signal CK, the reversed phase clock signal CKB, the output of the inverter 2 in the first data retaining circuit 18, the output of the inverter 3 in the first data retaining circuit 18, the (normal phase) output signal Q, the reversed phase output signal QB, ON/OFF operational state of the first data reading circuit 17 of the master side element 100, ON/OFF operational state of the first data retaining circuit 18 of the master side element 100, ON/OFF operational state of the second data reading circuit 19 of the slave side element 200, and ON/OFF operational state of the second data retaining circuit 20 of the slave side element 200.

First, the operation will be explained when the clock signal CK is at L level.

When the clock signal CK is at L level, the reversed phase clock signal CKB is input to the gate terminal of the NMOS 6 in the first data reading circuit 17. Accordingly, the gate voltage thereof is at H level. On the other hand, the clock signal CK is input to the gate terminals of the PMOS 4 and the PMOS 8. Accordingly, the gate voltage thereof is at L level. Therefore, the first data reading circuit 17 of the master side element 100 is in ON state.

When the clock signal CK is at L level, the clock signal CK is input to the gate terminal of the NMOS 1 in the first data retaining circuit 18. Accordingly, the gate voltage is at L level. Therefore, the first data retaining circuit 18 of the master side element 100 is at OFF state.

Further, when the clock signal CK is at L level, the clock signal CK is input to the gate terminal of the NMOS 16 of the second data reading circuit 19. Accordingly, the gate voltage thereof is at L level. The reversed phase clock signal CKB is input to the gate terminal of each of the PMOS 12 and the PMOS 14. Accordingly, the gate voltage thereof is at H level. Therefore, the second data reading circuit 19 of the slave side element 200 is in OFF state.

Further, when the clock signal CK is at L level, the reversed phase clock signal CKB is input to the gate terminal of the NMOS 9 in the second data retaining circuit 20. Accordingly, the gate voltage is at H level. Therefore, the second data retaining circuit 20 of the slave side element 200 is in ON state.

As described above, when the clock signal CK is at L level, the first data reading circuit 17 of the master side element 100 is in ON state. Accordingly, the data signal D and the reversed phase data signal DB input from the input terminals are read, and the states of the data signal D and the reversed phase data signal DB are reflected in the output of the inverter 2 and the output of the inverter 3, i.e., input/output of the first data retaining circuit 18 of the master side element 100.

When the clock signal CK is at L level, the second data reading circuit 19 of the slave side element 200 is in OFF state. However, the second data retaining circuit 20 of the slave side element 200 is in ON state. Accordingly, the slave side element 200 retains and outputs the output signal Q and the reversed phase output signal QB output by the second data reading circuit 19 of the slave side element 200 at a previous time in which the clock signal CK was at H level.

As shown in FIG. 3, the (normal phase) data signal D was at L level before the time A of the clock signal CK (rise), but is at H level after the time B (fall). Therefore, at the time B, the first data reading circuit 17 of the master side element 100 is in ON state, which changes the output of the inverter 2 to H level, and changes the output of the inverter 3 to L level in the first data retaining circuit 18.

Subsequently, the operation will be explained when the clock signal CK is at H level.

When the clock signal CK is at H level, the reversed phase clock signal CKB is input to the gate terminal of the NMOS 6 of the first data reading circuit 17 in the master side element 100. Accordingly, the gate voltage thereof is at L level. The clock signal CK is input to the gate terminal of each of the PMOS 4 and the PMOS 8. Accordingly, the gate voltage thereof is at H level. Therefore, the first data reading circuit 17 in the master side element 100 is in OFF state.

When the clock signal CK is at H level, the clock signal CK is input to the gate terminal of the NMOS 1 of the first data retaining circuit 18 in the master side element 100. Accordingly, the gate voltage thereof is at H level. Therefore, the first data retaining circuit 18 of the master side element 100 is in ON state.

Further, when the clock signal CK is at H level, the clock signal CK is input to the gate terminal of the NMOS 16 of the second data reading circuit 19 in the slave side element 200. Accordingly, the gate voltage thereof is at H level. On the other hand, the reversed phase clock signal CKB is input to the gate terminal of each of the PMOS 12 and the PMOS 14. Accordingly, the gate voltage thereof is at L level. Therefore, the second data reading circuit 19 of the slave side element 200 is in ON state.

Further, when the clock signal CK is at H level, the reversed phase clock signal CKB is input to the gate terminal of the NMOS 9 of the second data retaining circuit 20 in the slave side element 200. Accordingly, the gate voltage thereof is at L level. Therefore, the second data retaining circuit 20 of the slave side element 200 is in OFF state.

As described above, when the clock signal CK is at H level, the first data reading circuit 17 of the master side element 100 is in OFF state, but the first data retaining circuit 18 of the master side element 100 is in ON state. Accordingly, the first data retaining circuit 18 retains the output of the inverter 2 and the output of the inverter 3 output by the first data reading circuit 17 of the master side element 100 at a previous time in which the clock signal CK was at L level.

When the clock signal CK is at H level, the second data reading circuit 19 of the slave side element 200 is in ON state. Accordingly, the output signals of the inverter 2 and the inverter 3 are read, and are reflected in the output (QB) of the inverter 11 and the output (Q) of the inverter 10, i.e., input/output of the second data retaining circuit 20 of the slave side element 200.

As shown in FIG. 3, the output of the inverter 2 was at L level before the time A of the clock signal CK (rise), but is at H level after the time B (fall). Therefore, at the time C, the second data reading circuit 19 of the slave side element 200 is in ON state, which changes the output (Q) of the inverter 10 to H level and changes the output (QB) of the inverter 11 to L level in the second data retaining circuit 20.

According to the above operation, the flip-flop circuit according to the first embodiment is achieved.

The flip-flop circuit according to the first embodiment has the above structure. Therefore, when the first data reading circuit 17 of the master side element 100 is in ON state, the first data retaining circuit 18 of the master side element 100 is in OFF state. Alternatively, when the second data reading circuit 19 of the slave side element 200 is in ON state, the second data retaining circuit 20 of the slave side element 200 is in OFF state.

In the above operation of the flip-flop circuit according to the first embodiment, when the outputs of the first and second data reading circuits 17, 19 change from L level to H level or change oppositely, there is an effect of reducing the consumption current flowing through the inverters 2, 3, 10, 11, i.e., constituent elements of the first and second data retaining circuits 18, 20.

Subsequently, the reason why the flip-flop circuit according to the first embodiment solves the problem of the parasitic capacitance between the gate and the source of the inverter in the conventional flip-flop circuit.

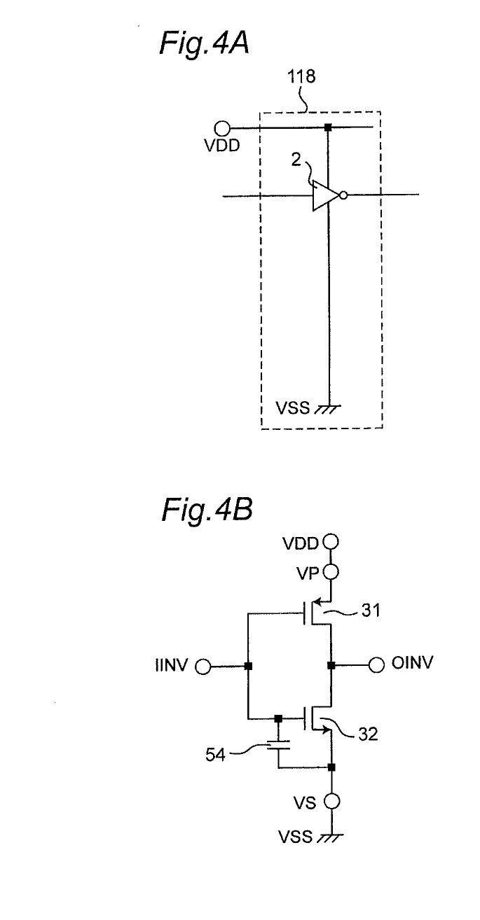

FIGS. 4A and 4B illustrate the conventional inverter circuit where inverter 2 is used, and is a circuit diagram illustrating the problem of the parasitic capacitance between the gate and the source in the conventional flip-flop circuit. FIG. 4A is a block diagram illustrating input/output relationship of the inverter circuit 118 in the conventional flip-flop circuit. FIG. 4B is a circuit configuration diagram more specifically illustrating the inverter circuit 118 as shown in FIG. 4A. The inverter circuit 118 as shown in FIG. 4A has the same structure as the inverter 102 as shown in FIG. 26A explained above. The power supply end VP of the inverter circuit 118 is connected to the high potential side power supply VDD, and the earthing end VS is connected to the low potential side power supply VSS. In FIG. 4B, reference numeral 54 denotes a parasitic capacitance between the gate and the source, which is formed between the gate and the source of the NMOS 32.

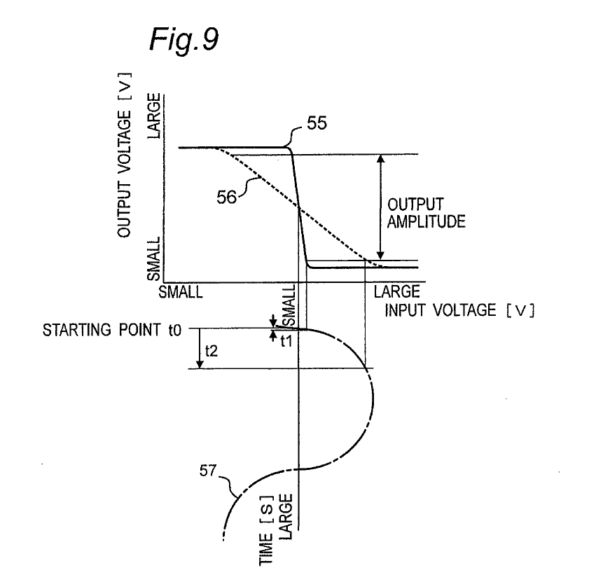

As described above, in the inverter circuit 118 as shown in FIGS. 4A and 4B, the source of the NMOS 32 is directly connected to the low potential side power supply VSS. Therefore, for example, when the inverter circuit 118 of FIGS. 4A and 4B is used in the configuration of the first embodiment, the parasitic capacitance between the gate and the source exerts action as the load of the first data reading circuit (17) serving as a stage previous thereto. As a result, there is a problem in that, when the inverter circuit as shown in FIGS. 9A and 4B is used, the maximum operating frequency is reduced.

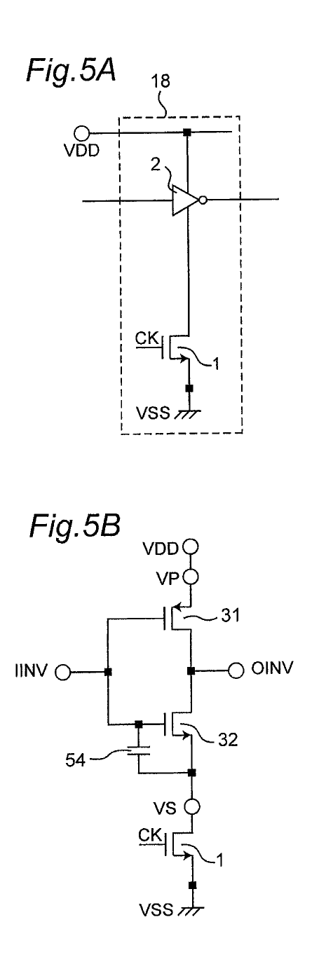

FIGS. 5A and 5B are circuit diagrams illustrating a case where the NMOS 1 and the inverter 2 are used in the first data retaining circuit 18 in the flip-flop circuit according to the first embodiment. FIG. 5A is a block diagram illustrating input/output relationship to the inverter 2 in the first data retaining circuit 18. FIG. 5B is a circuit configuration diagram specifically illustrating the first data retaining circuit 18 using the inverter 2 and the NMOS 1. In FIG. 5B, reference numeral 54 denotes the parasitic capacitance of the inverter 2.

As shown in FIG. 5B, in the first data retaining circuit 18, the PMOS 31 and the NMOS 32 are arranged. The source terminal of the PMOS 31 is the power supply end VP. The source terminal of the NMOS 32 is the earthing end VS. The gate terminal of the PMOS 31 and the gate terminal of the NMOS 32 are connected to form the input end IINV. The drain terminal of the PMOS 31 and the drain terminal of the NMOS 32 are connected to form an output end OINV.

As shown in FIG. 5B, a parasitic capacitance 54 exists between the gate and the source of the NMOS 32 of the inverter 2. However, the source terminal (VS) of the NMOS 32 is connected to the low potential side power supply VSS via the NMOS 1 driven and operated ON/OFF by the (normal phase) clock signal CK. Accordingly, at a time when the clock signal CK is at L level, the NMOS 1 in OFF state is interposed between the low potential side power supply VSS and the parasitic capacitance 54 between the gate and the source. As a result, the parasitic capacitance 54 between the gate and the source of the NMOS 32 does not exert action as the load of the first data reading circuit 17, and accordingly there is an effect of improving the maximum operating frequency in the flip-flop circuit.

Subsequently, the effects of the flip-flop circuit according to the first embodiment, i.e., the reduction of the consumption current and the improvement of the maximum operating frequency, will be explained in detail.

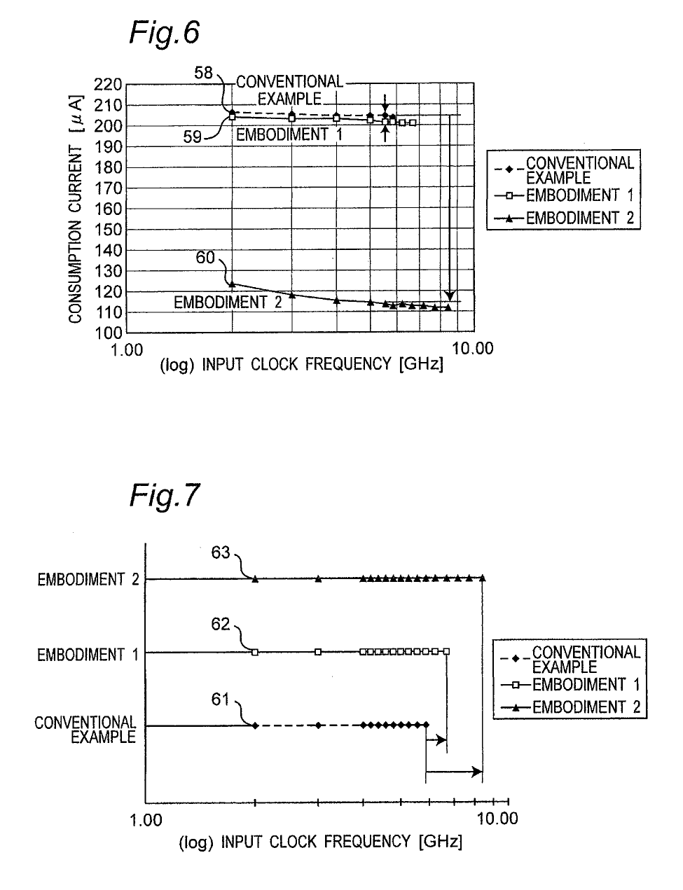

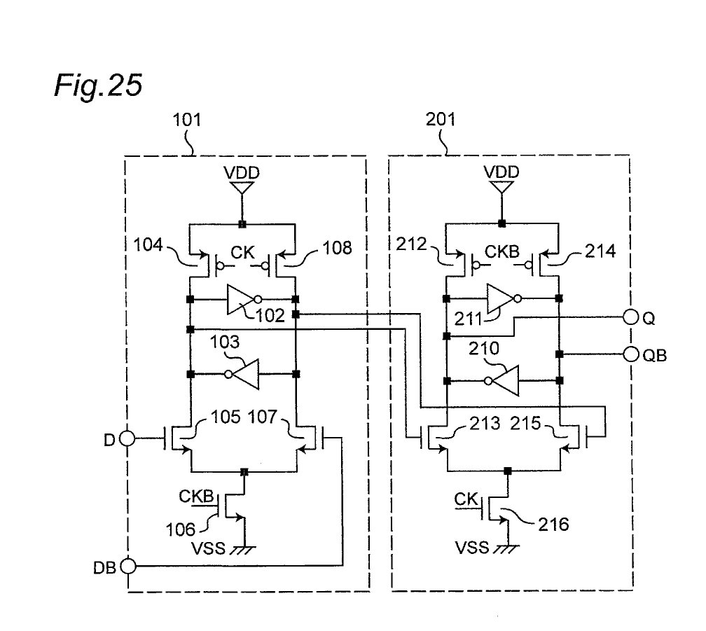

Table 1 to Table 4 and FIG. 6 and FIG. 7 are used to explain results obtained from simulations performed on the flip-flop circuit according to the first embodiment, the later-explained flip-flop circuit according to the second embodiment, and the conventional flip-flop circuit as shown in FIG. 25.

TABLE 1

| ITEM | UNIT | VALUE |
|---|---|---|
| VDD | V | 1.2 |
| ENVIRONMENTAL | ° C. | 27 |
| TEMPERATURE | | |
| CK/CKB AMPLITUDE | Vpp | 1.2 |
| D/DB AMPLITUDE | Vpp | 1.2 |

Table 1 shows conditions of simulations performed on the flip-flop circuit according to the first embodiment, the later-explained flip-flop circuit according to the second embodiment, and the conventional flip-flop circuit as shown in FIG. 25. As shown in Table 1, the conditions of the simulations were as follows. The high potential side power supply VDD was 1.2 V. The environmental temperature was 27 degrees Celsius. The amplitude of the clock signal CK/the reversed phase clock signal CKB was 1.2 Vpp. The amplitude of the data signal D/the reversed phase data signal DB was 1.2 Vpp.

TABLE 2

| Tr No. | L VALUE [μm] | W VALUE [μm] |
|---|---|---|
| NMOS(1) | 0.1 | 8 |
| PMOS(4), (104) | 0.1 | 1 |
| NMOS(5), (105) | 0.1 | 4 |
| NMOS(6), (106) | 0.1 | 8 |
| NMOS(7), (107) | 0.1 | 4 |
| PMOS(8), (108) | 0.1 | 1 |
| NMOS(9) | 0.1 | 8 |
| PMOS(12), (212) | 0.1 | 1 |
| NMOS(13), (213) | 0.1 | 4 |
| PMOS(14), (214) | 0.1 | 1 |
| NMOS(15), (215) | 0.1 | 4 |
| NMOS(16), (216) | 0.1 | 8 |
| PMOS(31) | 0.1 | 4 |
| NMOS(32) | 0.1 | 2 |

Table 2 shows the sizes of CMOS transistors used for the simulations performed on the flip-flop circuit according to the first embodiment, the later-explained flip-flop circuit according to the second embodiment, and the conventional flip-flop circuit as shown in FIG. 25.

An L value is a gate length [μm] of a CMOS transistor. A W value is a gate width [μm] of a CMOS transistor. It should be noted that the L values of all the CMOS transistors were 0.1 μm. The W values of the NMOS 1, the NMOS 6 (106), the NMOS 9, and the NMOS 16 (216) were 8 μm. The W values of the PMOS 4 (104), the PMOS 8 (108), the PMOS 12 (212), and the PMOS 14 (214) were 1 μm. The W values of the NMOS 15(105), the NMOS 7 (107), the NMOS 13 (213), the NMOS 15 (215), and the PMOS 31 were 4 μm. The W value of the NMOS 32 was 2 μm. It should be noted that the numbers in the parentheses denote the CMOS transistors in the conventional flip-flop circuit as shown in FIG. 25.

FIG. 6 is a graph for comparing consumption currents in the flip-flop circuit according to the first embodiment (white square), the later-explained flip-flop circuit according to the second embodiment (black triangle), and the conventional flip-flop circuit as shown in FIG. 25 (black rhombus).

In the single logarithm graph of FIG. 6, when the clock signal CK and the reversed phase clock signal CKB having input clock frequencies [GHz] as shown in the horizontal axis are given, the data signal D and the reversed phase data signal DB are changed from L level to H level, and operation is simulated until the output signal Q and the reversed phase output signal QB are transmitted, whereby average current consumed in the flip-flop circuit are plotted as consumption currents in the vertical axis. In FIG. 6, reference numeral 58 denotes a simulation result (black rhombus) of a consumption current in the conventional flip-flop circuit, and reference numeral 59 denotes a simulation result (white square) of a consumption current in the flip-flop circuit according to the first embodiment. It should be noted that reference numeral 60 denotes a simulation result (black triangle) of a consumption current in a later-explained flip-flop circuit according to the second embodiment.

As is evident from the result of FIG. 6, the consumption current of the simulation result in the flip-flop circuit according to the first embodiment is less than the consumption current of the simulation result in the conventional flip-flop circuit.

TABLE 3

| | SIMULATION RESULT | | |
|---|---|---|---|
| | CONSUMPTION | RATE WITH | |
| | CURRENT [μA] | RESPECT TO | |
| SIMULATION | DURING OPERATION | CONVENTIONAL | |
| CIRCUIT | AT 5.56 GHz | EXAMPLE [%] | DATA |
| PRIOR ART | 204 | 100 | FIG. 6 No. 58 |
| EMBODIMENT 1 | 201 | 98 | FIG. 6 No. 59 |
| | | (2% REDUCED) | |
| EMBODIMENT 2 | 114 | 55 | FIG. 6 No. 60 |
| | | (45% REDUCED) | |

FRACTIONAL PORTIONS ARE DROPPED

Table 3 is a table for comparing consumption currents in the flip-flop circuit according to the first embodiment, the later-explained flip-flop circuit according to the second embodiment, and the conventional flip-flop circuit as shown in FIG. 25. In Table 3, specific consumption current values obtained from the simulation results as shown in FIG. 6 are compared when 5.56 GHz is input. The simulation result of the consumption current in the conventional flip-flop circuit is 204 μA, whereas the simulation result of the consumption current in the flip-flop circuit according to the first embodiment is 201 μA. This means that the consumption current is reduced by 2% compared with the conventional flip-flop circuit.

FIG. 7 is a figure for comparing maximum operating frequencies in the flip-flop circuit according to the first embodiment, the later-explained flip-flop circuit according to the second embodiment, and the conventional flip-flop circuit as shown in FIG. 25.

In the comparison diagram of FIG. 7, when the clock signal CK and the reversed phase clock signal CKB having input clock frequencies [GHz] as shown in the horizontal axis are given, the data signal D and the reversed phase data signal DB are changed from L level to H level, and operation is simulated until the output signal Q and the reversed phase output signal QB are transmitted, whereby the highest operation frequency is plotted as a maximum operation frequency at which operation can be normally performed to change the outputs of the output signal Q and the reversed phase output signal QB based on the inputs of the data signal D and the reversed phase data signal DB.

In FIG. 7, reference numeral 61 denotes a simulation result (black rhombus) of a maximum operating frequency in the conventional flip-flop circuit, and reference numeral 62 denotes a simulation result (white square) of a maximum operating frequency in the flip-flop circuit according to the first embodiment. It should be noted that reference numeral 63 denotes a simulation result (black triangle) of a maximum operating frequency in the later-explained flip-flop circuit according to the second embodiment. As is evident from the result of FIG. 7, the maximum operating frequency of the simulation result in the flip-flop circuit according to the first embodiment is less than the maximum operating frequency of the simulation result in the conventional flip-flop circuit.

TABLE 4

| | SIMULATION RESULT | | |
|---|---|---|---|
| | | RATE WITH | |
| | | RESPECT TO | |
| SIMULATION | MAXIMUM OPERATION | CONVENTIONAL | |
| CIRCUIT | FREQUENCY [GHz] | EXAMPLE [%] | DATA |
| PRIOR ART | 5.88 | 100 | FIG. 7 No. 61 |
| EMBODIMENT 1 | 6.67 | 113 | FIG. 7 No. 62 |
| | | (13% IMPROVED) | |
| EMBODIMENT 2 | 8.33 | 141 | FIG. 7 No. 63 |
| | | (41% IMPROVED) | |

FRACTIONAL PORTIONS ARE DROPPED

Table 4 is a table for comparing maximum operating frequencies in the flip-flop circuit according to the first embodiment, in the later-explained flip-flop circuit according to the second embodiment, and in the conventional flip-flop circuit as shown in FIG. 25. In Table 4, specific numerals of the maximum operating frequencies obtained from the simulation results as shown in FIG. 7 are compared. The simulation result of the maximum operating frequency in the conventional flip-flop circuit is 5.88 GHz, whereas the simulation result of the maximum operating frequency in the flip-flop circuit according to the first embodiment is 6.67 GHz. This means that the maximum operating frequency is improved by 13% compared with the conventional flip-flop circuit.

As described above, the simulation result of the flip-flop circuit according to the first embodiment proves that the flip-flop circuit according to the first embodiment has great effects in that the consumption current is reduced 2% and the maximum operating frequency is improved 13%, compared with the conventional flip-flop circuit.

### Second Embodiment

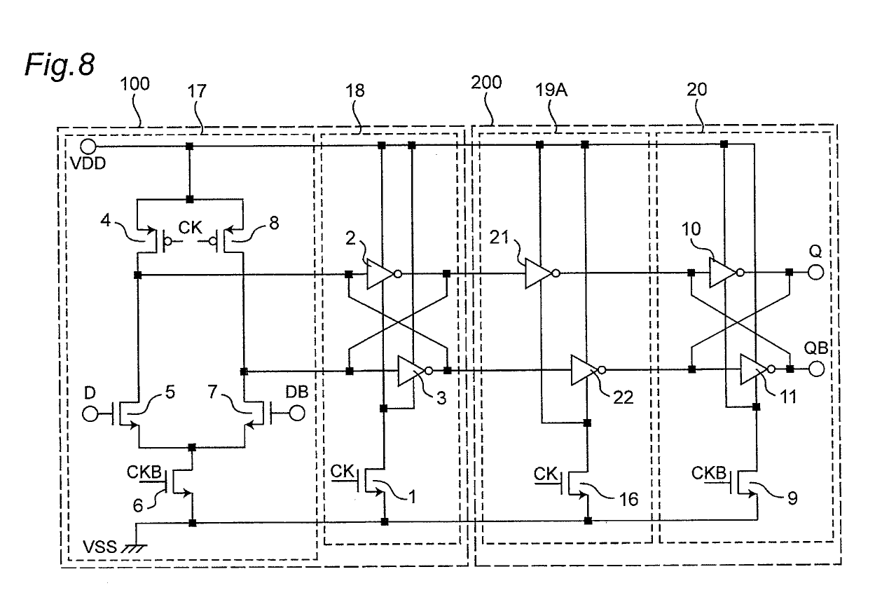

As shown in the block diagram of FIG. 1 explained above, in the flip-flop circuit according to the second embodiment of the present invention, the master side element 100 includes the first data reading circuit 17 and the first data retaining circuit 18, and the slave side element 200 includes a second data reading circuit 19A (see FIG. 8) and the second data retaining circuit 20. However, in the flip-flop circuit according to the second embodiment, the first data reading circuit 17 is constituted by a differential circuit, and the first data retaining circuit 18, the second data reading circuit 19A, and the second data retaining circuit 20 are constituted by inverter circuits. In the flip-flop circuit according to the second embodiment, power supplies of the first data retaining circuit 18 and the second data reading circuit 19A are controlled by the clock signal CK input from the outside in the same manner as the flip-flop circuit according to the first embodiment. Power supplies of the first data reading circuit 17 and the second data retaining circuit 20 are controlled by the reversed phase clock signal CK having a phase opposite to the clock signal CK. Thus, the operation of the flip-flop circuit is achieved.

As described above, in the flip-flop circuit according to the second embodiment, the second data reading circuit 19A of the slave side element 200 is constituted by the inverter circuit. Therefore, the second data reading circuit 19A flows a consumption current only in a time in which the CMOS transistor constituting the inverter circuit operates in a saturation characteristic region, and flows only little consumption current while they operate in a linear characteristic region. As a result, the flip-flop circuit according to the second embodiment achieves an effect of reducing the average consumption current.

Further, in the flip-flop circuit according to the second embodiment, the second data reading circuit 19A of the slave side element 200 is constituted by the inverter circuit. Therefore, the flip-flop circuit according to the second embodiment achieves the following effects. The gain, i.e., variation of output in response to variation of input voltage is increased. The operation speed of the output signal in response to the input signal is improved. In addition, the maximum operating frequency is improved.

The configuration and operation of the flip-flop circuit according to the second embodiment will be hereinafter explained specifically in more detail.

FIG. 8 is a circuit diagram illustrating a specific configuration of the flip-flop circuit according to the second embodiment. In FIG. 8, constituent elements having substantially the same functions and configurations as those in the flip-flop circuit according to the first embodiment as shown in FIG. 2 explained above are denoted with the same reference numerals, and the description thereabout is omitted. The configuration of the flip-flop circuit according to the second embodiment is different from the configuration of the flip-flop circuit according to the first embodiment with respect to the configuration of the second data reading circuit 19A of the slave side element 200 and relationship of connections between the second data reading circuit 19A of the slave side element 200 and the first data retaining circuit 18 of the master side element 100 and between the second data reading circuit 19A of the slave side element 200 and the second data retaining circuit 20 of the slave side element 200.

As shown in FIG. 8, the second data reading circuit 19A in the flip-flop circuit according to the second embodiment includes inverters 21, 22 and the NMOS 16 driven by the (normal phase) clock signal CK input to the gate terminal. In the second data reading circuit 19A, the earthing end of each of the inverters 21, 22 is connected to the low potential side power supply VSS via the NMOS 16 driven by the (normal phase) clock signal. In the second data reading circuit 19A, a power supply end of each of the inverters 21, 22 is connected to a high potential side power supply VDD.

The input end of the inverter 21 is connected to the output end of the inverter 2, i.e., a constituent element of the first data retaining circuit 18 of the master side element 100. The output end of the inverter 21 is connected to the output end of the inverter 11, i.e., a constituent element of the second data retaining circuit 20 of the slave side element 200. Namely, the output end of the inverter 21 is connected to the output terminal of the reversed phase output signal QB.

On the other hand, the input end of the inverter 22 is connected to the output end of the inverter 3, i.e., a constituent element of the first data retaining circuit 18 of the master side element 100. The output end of the inverter 22 is connected to the output end of the inverter 10, i.e., a constituent element of the second data retaining circuit 20 of the slave side element 200. Namely, the output end of the inverter 22 is connected to the output terminal of the output signal Q.

In the flip-flop circuit according to the second embodiment, the first data reading circuit 17 of the master side element 100, the first data retaining circuit 18 of the master side element 100, and the second data retaining circuit 20 of the slave side element 200 are the same as those in the first embodiment shown in FIG. 2 explained above. Therefore, the detailed description about these circuits is omitted here. Further, for example, the specific configurations of the inverters 21, 22 may be the same as the configuration of the inverter circuit as shown in FIG. 26B explained above.

The operation of the flip-flop circuit according to the second embodiment having the above configuration will be explained with reference to FIG. 8 and the timing hart of FIG. 3 used in the explanation about the first embodiment. The operation of the flip-flop circuit according to the second embodiment is substantially the same as the operation of the flip-flop circuit according to the first embodiment. Accordingly, the timing chart as shown in FIG. 3 is used to explained the operation of the flip-flop circuit according to the second embodiment. The operation indicated by the reference numerals described in FIG. 3 is the same as the operation of the flip-flop circuit as shown in each of the first embodiment and the second embodiment.

First, the operation will be explained when the clock signal CK is at L level.

When the clock signal CK is at L level, the reversed phase clock signal CKB is input to the gate terminal of the NMOS 6 in the first data reading circuit 17. Accordingly, the gate voltage thereof is at H level. On the other hand, the clock signal CK is input to the gate terminals of the PMOS 4 and the PMOS 8. Accordingly, the gate voltage thereof is at L level. Therefore, the first data reading circuit 17 of the master side element 100 is in ON state.

When the clock signal CK is at L level, the clock signal CK is input to the gate terminal of the NMOS 1 in the first data retaining circuit 18. Accordingly, the gate voltage is at L level. Therefore, the first data retaining circuit 18 of the master side element 100 is at OFF state.

Further, when the clock signal CK is at L level, the clock signal CK is input to the gate terminal of the NMOS 16 of the second data reading circuit 19A. Accordingly, the gate voltage thereof is at L level. Therefore, the second data reading circuit 19A of the slave side element 200 is in OFF state.

Further, when the clock signal OK is at L level, the reversed phase clock signal CKB is input to the gate terminal of the NMOS 9 in the second data retaining circuit 20. Accordingly, the gate voltage is at H level. Therefore, the second data retaining circuit 20 of the slave side element 200 is in ON state.

As described above, when the clock signal CK is at L level, the first data reading circuit 17 of the master side element 100 is in ON state. Accordingly, the data signal D and the reversed phase data signal DB input from the input terminals are read, and the states of the data signal D and the reversed phase data signal DB are reflected in the output of the inverter 2 and the output of the inverter 3, i.e., input/output of the first data retaining circuit 18 of the master side element 100.

When the clock signal CK is at L level, the second data reading circuit 19A of the slave side element 200 is in OFF state. However, the second data retaining circuit 20 of the slave side element 200 is in ON state. Accordingly, the slave side element 200 retains and outputs the output signal Q and the reversed phase output signal QB output by the second data reading circuit 19A of the slave side element 200 at a previous time in which the clock signal CK was at H level.

As shown in FIG. 3, the (normal phase) data signal D was at L level before the time A of the clock signal CK (rise), but is at H level after the time B (fall). Therefore, at the time B, the first data reading circuit 17 of the master side element 100 is in ON state, which changes the output of the inverter 2 to H level, and changes the output of the inverter 3 to L level in the first data retaining circuit 18.

Subsequently, the operation will be explained when the clock signal CK is at H level.

When the clock signal CK is at H level, the reversed phase clock signal CKB is input to the gate terminal of the NMOS 6 of the first data reading circuit 17 in the master side element 100. Accordingly, the gate voltage thereof is at L level. The clock signal CK is input to the gate terminal of each of the PMOS 4 and the PMOS 8. Accordingly, the gate voltage thereof is at H level. Therefore, the first data reading circuit 17 in the master side element 100 is in OFF state.

When the clock signal CK is at H level, the clock signal CK is input to the gate terminal of the NMOS 1 of the first data retaining circuit 18 in the master side element 100. Accordingly, the gate voltage thereof is at H level. Therefore, the first data retaining circuit 18 of the master side element 100 is in ON state.

Further, when the clock signal CK is at H level, the clock signal CK is input to the gate terminal of the NMOS 16 of the second data reading circuit 19A in the slave side element 200. Accordingly, the gate voltage thereof is at H level. Therefore, the second data reading circuit 19A of the slave side element 200 is in ON state.

Further, when the clock signal CK is at H level, the reversed phase clock signal CKB is input to the gate terminal of the NMOS 9 of the second data retaining circuit 20 in the slave side element 200. Accordingly, the gate voltage thereof is at L level. Therefore, the second data retaining circuit 20 of the slave side element 200 is in OFF state.

As described above, when the clock signal CK is at H level, the first data reading circuit 17 of the master side element 100 is in OFF state, but the first data retaining circuit 18 of the master side element 100 is in ON state. Accordingly, the first data retaining circuit 18 retains the output of the inverter 2 and the output of the inverter 3 output by the first data reading circuit 17 of the master side element 100 at a previous time in which the clock signal CK was at L level.

When the clock signal CK is at H level, the second data reading circuit 19A of the slave side element 200 is in ON state. Accordingly, the output signals of the inverter 2 and the inverter 3 are read, and are reflected in the output (QB) of the inverter 11 and the output (Q) of the inverter 10, i.e., input/output of the second data retaining circuit 20 of the slave side element 200.

As shown in FIG. 3, the output of the inverter 2 was at L level before the time A of the clock signal CK (rise), but is at H level after the time B (fall). Therefore, at the time C, the second data reading circuit 19A of the slave side element 200 is in ON state, which changes the output (Q) of the inverter 10 to H level and changes the output (QB) of the inverter 11 to L level in the second data retaining circuit 20.

According to the above operation, the flip-flop circuit according to the second embodiment is achieved.

As described above, in the flip-flop circuit according to the second embodiment, the second data reading circuit 19A of the slave side element 200 is constituted by the inverter circuit including the inverter 21 and the inverter 22. For example, as shown in FIG. 26B, each of the inverters 21, 22 is constituted by the PMOS 31 and the NMOS 32. Therefore, the flip-flop circuit according to the second embodiment flows a consumption current only in a time in which the PMOS 31 and the NMOS 32 operate in the saturation characteristic region, and flows only little consumption current while they operate in the linear characteristic region. As a result, the flip-flop circuit according to the second embodiment achieves an effect of reducing the average consumption current.

Further, in the flip-flop circuit according to the second embodiment, the second data reading circuit 19A of the slave side element 200 is constituted by the inverter circuit including the inverter 21 and the inverter 22. Therefore, the flip-flop circuit according to the second embodiment achieves the following effects. The gain, i.e., variation of output in response to variation of input voltage is increased. The operation speed of the output signal in response to the input signal is improved. In addition, the maximum operating frequency is improved.

Subsequently, the effects of the flip-flop circuit according to the second embodiment of the present invention will be explained using numerical expressions.

First, in the flip-flop circuit according to the second embodiment, the operation speed and the consumption current of the second data reading circuit 19A of the slave side element 200 will be compared and explained using the numerical expressions.

The expression (1) and the expression (2) below are indicated in Kenji TANIGUCHI, Introduction to CMOS Analog Circuit, Fourth Edition, CQ Publishing Co., Ltd., Aug. 1, 2006, pp. 33 to 36. The expression (1) and expression (2) are well-known expressions about electrical characteristics of CMOS transistors. The expression (1) is a numerical expression of linear characteristics applicable when a drain-source voltage (VDS) of the CMOS transistor is less than a value obtained by subtracting a threshold value voltage (Vt) from a gate-source voltage (VGS).

ID=β[(VGS−Vt)−(1/2)VDS]VDS (1)

In the expression (1), “ID” denotes a drain current, “VGS” denotes a gate-source voltage, “Vt” denotes a threshold voltage, and “VDS” denotes a drain-source voltage. It should be noted that β=(W/L)μ·Cox holds, in which “L” denotes a gate length, “W” denotes a gate width, “μ” denotes a carrier mobility, and Cox” denotes a capacitance per unit area of the gate oxide film.

ID=(β/2)[(VGS−Vt)²](1+λVDS)≈(β/2)(VGS−Vt)² (2)

The expression (2) is a numerical expression of saturation characteristics applicable when a drain-source voltage (VDS) of the CMOS transistor is less than a value obtained by subtracting a threshold value voltage (Vt) from a gate-source voltage (VGS).

In the expression (2), the same elements as those of the expression (1) are denoted with the same variables, and the description thereabout is omitted. In the expression (2), “λ” denotes a magnitude of output conductance representing a variation of drain current.

In the below explanation, the reference numerals used in the drawings of the embodiments are used to explain the elements in the numerical expressions for except for the explanation about a well-known expression. For the sake of simplicity of explanation, the characteristic of each CMOS transistor is assumed to be the same, and the elements of the numerical expression, “β” and “Vt”, are assumed to be the same.

The inverter 21 of the second data reading circuit 19A, i.e., a constituent element in the flip-flop circuit according to the second embodiment as shown in FIG. 8, will be explained. In the below explanation, the inverter 21 is explained simply as inverter. Accordingly, the inverter circuit including the PMOS 31 and the NMOS 32 as shown in FIG. 26B is used for the explanation.

In the inverter circuit as shown in FIG. 26B, the voltage input to the input terminal IINV is represented as VIINV, and the voltage output to the input terminal OINV is represented as VOINV.

When the input voltage VIINV serving as the gate voltage of the NMOS 32 is less than the threshold value voltage Vt, the drain current of the NMOS 32 hardly flows. Accordingly, almost the same amount of current as the drain current of the NMOS 32 flows in the PMOS 31 connected to the NMOS 32. Therefore, the drain current of the PMOS 31 is given by the expression (3) obtained from the expression (1). The PMOS 31 goes into the linear operation region, and the source-drain voltage (VDS) of the PMOS 31 becomes extremely small. As a result, the consumption current of the inverter circuit hardly flows, and the output voltage VOINV becomes almost the same as the power supply voltage VDD.

β[(VIINV−VDD+Vt)−(1/2)(VOINV−VDD)]×(VOINV−VDD)≈0 (3)

When the input voltage VIINV is increased, the NMOS 32 goes into the saturation characteristic region. However, until the drain current reaches the saturation drain current of the PMOS 31, the PMOS 31 operates in the linear characteristic region. At this occasion, the current flowing in the NMOS 32 and the current flowing in the PMOS 31 are the same. Accordingly, the following expression (4) holds based on the expression (1) and the expression (2). Even under this condition, the PMOS 31 is in the linear characteristic region, which hardly allows flow of the consumption current. Accordingly, the source-drain voltage of the PMOS 31, (VDS=VOINV−VDD) is small, and the output voltage VOINV is almost the same as the power supply voltage VDD.

β[(VIINV−VDD+Vt)−(1/2)(VOINV−VDD)]×(VOINV−VDD)=(β/2)(VIINV−Vt)² (4)

Further, when the input voltage VIINV is increased, and both of the NMOS 32 and the PMOS 31 go into the saturation characteristic region, the currents thereof are balanced, and the expression (5) obtained from the expression (2) is given. At this occasion, the inverter circuit consumes current, and the output voltage VOINV performs operation to change in proportional to the input voltage VIINV.

(β/2)[(VIINV−VDD+Vt)²](1+λ|VOINV−VDD|)=(β/2)[(VIINV−Vt)²](1+λVOINV) (5)

Subsequently, as the input voltage VIINV is increased, operation is performed in which the PMOS 31 and the NMOS 32 are replaced with each other in the expression (3) and the expression (4). In the expression (3), the expression (4), and the expression (5), the condition in which the inverter circuit consumes current is only the expression (5). In a case where the input voltage VIINV changes from L level to H level or from H level to L level as the time passes, the inverter circuit consumes current only in a limited period of time.

The condition in which the inverter circuit changes the output voltage VOINV in proportional to the input voltage VIINV is only the expression (5), and the operation is finished in such a manner that the output amplitude is changed from H level to L level or L level to H level under a limited input condition. Therefore, a high gain can be obtained. In a case where the input voltage VIINV changes from L level to H level or from H level to L level as the time passes, operation is finished in such a manner that the output amplitude is changed from H level to L level or from L level to H level in a limited period of time because the inverter circuit has a high gain. Therefore, a high operation speed can be obtained.

In the above-explained flip-flop circuit according to the first embodiment, each source terminal of the NMOS 13 and the NMOS 15 of the second data reading circuit 19 is connected to a differential amplifier circuit, in which the NMOS 16 provides source currents to the NMOS 13 and the NMOS 15. Now, operation of the input stage of the differential amplifier circuit will be hereinafter explained.

The following expression (6) is given, where drain currents of the NMOS 13, the NMOS 15, and the NMOS 16 are denotes as I13, I15, I16, respectively.

I16=I13+I15 (6)

The relationships between the input voltage and the current in the NMOS 13 and the NMOS 15 are given by the expression (7) and the expression (8) based on the numerical expression of saturation characteristics of the expression (2). In the expression (7), “VGS13” denotes a gate-source voltage of the NMOS 13. In the expression (8), “VGS15” is a gate-source voltage of the NMOS 15.

VGS13=Vt+(2·I13/β)^{(1/2)} (7)

VGS15=Vt+(2·I15/β)^{(1/2)} (8)

A differential voltage between VGS13 and VGS15, i.e., differential input voltage (VIN), is defined by the following expression (9), based on the expression (7) and the expression (8).

VIN=VGS13−VGS15=[(2/β)^{(1/2)}][(I13)^{(1/2)}−(I15)^{(1/2)}] (9)

The drain currents of the NMOS 13 and the NMOS 15 are given by the following expression (10) based on the expression (6) and the expression (9).

I13,I15=(I16/2)±(I16/2)VIN[(β/I16)−(β²)(VIN²)/4(I16²)]^{(1/2)} (10)

According to the expression (10), where there is no difference between the input voltage of the NMOS 13 and the input voltage of the NMOS 15, the drain current flowing in either of the NMOS 13 and the NMOS 15 is half of the drain current of the NMOS 16. When there is a difference between the input voltages, the difference between the drain currents of them both (I13-I15) increases in proportional to the input voltage difference VIN. Further, when the input voltage difference VIN increases, one of the CMOS transistors is shut off under the condition of the following expression (11), and all the current I16 flows through the other of the CMOS transistors.

|VIN|>(2·I16/β)^{(1/2)} (11)

Regardless of the input condition, the drain current I16 of the NMOS 16 is always consumed as a consumption current in the above operation.

On the other hand, the condition in which the differential amplifier circuit changes the output currents I13, I15 in proportional to the input voltage difference VIN is the range shown by the expression (12) based on the expression (11).

|VIN|≦(2·I16/β)^{(1/2)} (12)

According to the above explanation about the operation using the numerical expressions, the second data reading circuit 19 of the slave side element 200 in the flip-flop circuit according to the first embodiment always consumes the current I16 regardless of the input condition, whereas the second data reading circuit 19A of the slave side element 200 in the flip-flop circuit according to the second embodiment as shown in FIG. 8 consumes current only in the condition of the expression (5). This means that the consumption current is configured to be generated only in the limited period in which the input voltage VIINV changes from L level to H level or from H level to L level as the time passes. As a result, the flip-flop circuit according to the second embodiment has an effect of reducing the hourly average consumption current.

Further, the condition in which the differential amplifier circuit in the second data reading circuit 19 of the slave side element 200 of the flip-flop circuit according to the first embodiment changes the output currents 113 and 115 in proportional to the input voltage difference VIN is given as the range shown in the expression (12). In this range, the change of the output can be finished in response to the input voltage difference VIN.

Compared with the operation of the differential amplifier circuit of the second data reading circuit 19 according to the first embodiment, only the expression (5) is the condition in which the output voltage VOINV is changed in proportional to the input voltage VIINV by the inverters 21, 22 constituting the second data reading circuit 19A of the slave side element 200 according to the second embodiment as shown in FIG. 8, and this operation finishes changing of the output amplitude under the limited input condition. Therefore, the data reading circuit 19A of the flip-flop circuit according to the second embodiment has a higher gain than the second data reading circuit 19 of the flip-flop circuit according to the first embodiment. Further, when the input voltage changes as the time passes, the inverter circuit finishes changing of the output amplitude in a limited short time due to the high gain in the flip-flop circuit according to the second embodiment. Therefore, the operation speed of the flip-flop circuit according to the second embodiment is faster than the operation speed of the differential amplifier circuit of the first data reading circuit 19 in the flip-flop circuit according to the first embodiment.

FIG. 9 shows an input/output characteristic curve (curve indicated by a solid line) 55 of the inverter circuit of the second data reading circuit 19A according to the second embodiment, an input/output characteristic curve (curve indicated by broken line) 56 of the differential amplification circuit of the second data reading circuit 19 according to the first embodiment, and an input signal (alternate long and short dashed line) 57 to the second data reading circuits 19 and 19A.

The input/output characteristic curve 55 of the inverter circuit of the second data reading circuit 19A according to the second embodiment show the input/output characteristics of the inverter circuit obtained from the expression (3), the expression (4), and the expression (5). The input/output characteristic curve 56 of the differential amplifier circuit of the second data reading circuit 19 according to the first embodiment represents the input/output characteristics of the differential amplifier circuit obtained from the expression (10) and the expression (11).

As shown in FIG. 9, the input/output characteristic curve 55 of the second data reading circuit 19A (inverter circuit) according to the second embodiment changes more rapidly than the input/output characteristic curve 56 of the second data reading circuit 19 (differential amplifier circuit) according to the first embodiment. Therefore, the same output amplitude can be output in an extremely short period of time.

In FIG. 9, “t0” denotes a starting time of the input signal 57, “t1” denotes an output time of the second data reading circuit 19A (inverter circuit), and “t2” denotes an output time of the second data reading circuit 19 (differential amplifier circuit).

As described above, the input/output characteristics of the inverter circuit of the second data reading circuit 19A according to the second embodiment change rapidly, and the time t1 for outputting a desired output amplitude with respect to the starting time t0 of the input signal 57 is an extremely short time, compared with the time t2 in which the differential amplifier circuit outputs the same output amplitude. This indicates that the gain, i.e., variation of output voltage in response to variation of input voltage is high, and the operation speed for outputting a signal in response to the input signal 57 has been improved. As described above the inverter circuit of the second data reading circuit 19A according to the second embodiment has a great effect of greatly improving the maximum operating frequency, compared with the differential amplifier circuit.

Subsequently, with regard to the flip-flop circuit according to the second embodiment, the result obtained from the simulation on the flip-flop circuit according to the first embodiment and the conventional flip-flop circuit as shown in FIG. 25 will be explained with reference to Table 1 to Table 4, FIG. 6, and FIG. 7 used in the first embodiment. The conditions of the simulation and the size of the CMOS transistor are the same as those in Table 1 and Table 2 explained in the first embodiment, and the description thereabout is omitted.

As explained above, FIG. 6 is a graph for comparing consumption currents in the flip-flop circuit according to the first embodiment (white square), the flip-flop circuit according to the second embodiment (black triangle), and the conventional flip-flop circuit as shown in FIG. 25 (black rhombus). In FIG. 6, reference numeral 60 denotes the simulation result (black triangle) of the consumption current in the flip-flop circuit according to the second embodiment.

As is evident from the result shown in FIG. 6, in the simulation result of the flip-flop circuit according to the second embodiment, the consumption current is greatly reduced, compared with the conventional flip-flop circuit and the flip-flop circuit according to the first embodiment.

As shown in Table 3, when 5.56 GHz is input, the simulation result of the consumption current in the conventional flip-flop circuit is 204 μA, whereas the simulation result of the flip-flop circuit according to the second embodiment is 114 μA. This means that the consumption current is greatly reduced by 45% compared with the conventional flip-flop circuit.

Further, as shown in FIG. 7, the maximum operating frequency in the simulation result of the flip-flop circuit according to the second embodiment is higher than that in the simulation result of the conventional flip-flop circuit.

Table 4 is a table for comparing specific numeric values of maximum operating frequencies based on the simulation result shown in FIG. 7. The simulation result of the maximum operating frequency in the conventional flip-flop circuit is 5.88 GHz, whereas the simulation result thereof of the flip-flop circuit according to the second embodiment is 8.33 GHz. Therefore, the improvement by 41% has been achieved, compared with the conventional flip-flop circuit.

As described above, compared with the conventional flip-flop circuit, the simulation result of the flip-flop circuit according to the second embodiment proves that the flip-flop circuit according to the second embodiment achieves great effects of 45% reduction in the consumption current and 41% improvement in the maximum operating frequency. Further, the flip-flop circuit according to the second embodiment achieves great effects in the consumption current and the maximum operating frequency over the flip-flop circuit according to the first embodiment.

### Third Embodiment

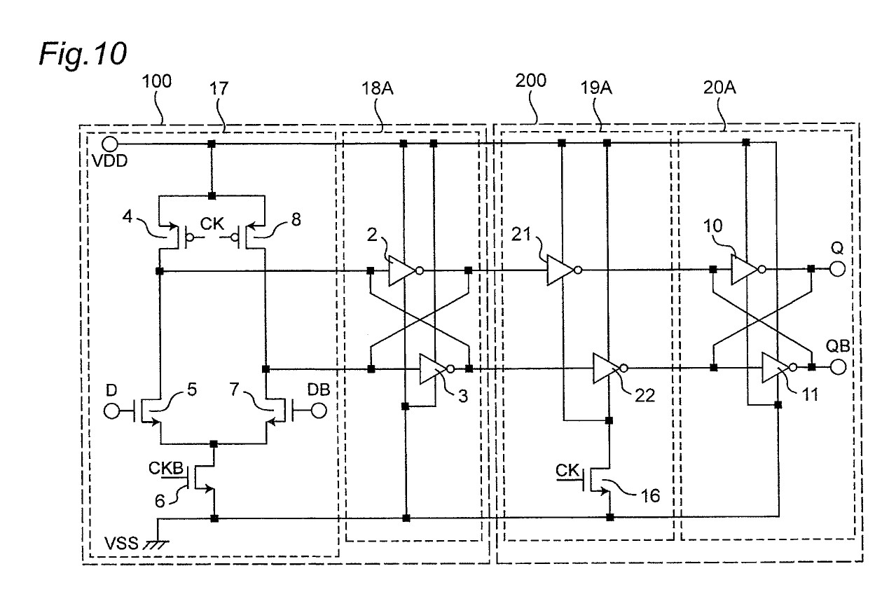

FIG. 10 is a circuit diagram illustrating a flip-flop circuit according to the third embodiment of the present invention. In FIG. 10, constituent elements having substantially the same functions and configurations as those in the flip-flop circuit according to the second embodiment as shown in FIG. 8 explained above are denoted with the same reference numerals, and the description thereabout is omitted.

In the flip-flop circuit according to the third embodiment, the first data reading circuit 17 is constituted by a differential circuit, and a first data retaining circuit 18A, a second data reading circuit 19A, and a second data retaining circuit 20A are constituted by inverter circuits, in the same manner as the flip-flop circuit according to the second embodiment. The configuration of the flip-flop circuit according to the third embodiment is different from the configuration of the flip-flop circuit according to the second embodiment in the configurations of the first data retaining circuit 18A of the master side element 100 and the second data retaining circuit 20A of the slave side element 200.

The difference of the flip-flop circuit according to the third embodiment from the flip-flop circuit according to the second embodiment will be hereinafter explained with reference to FIG. 10.

In the flip-flop circuit according to the third embodiment, the earthing end of each of the inverters 2, 3 of the first data retaining circuit 18A of the master side element 100 is connected to the low potential side power supply VSS, and the power supply end thereof is connected to the high potential side power supply VDD. Further the first data retaining circuit 18A is configured such that the input end and the output end of the inverter 2 are interconnected with the output end and the input end of the inverter 3.

In the second data retaining circuit 20A of the slave side element 200, the earthing end of each of the inverters 10, 11 is connected to the low potential side power supply VSS, and the power supply end thereof is connected to the high potential side power supply VDD. Further the second data retaining circuit 20A is configured such that the input end and the output end of the inverter 10 are interconnected with the output end and the input end of the inverter 11.

As described above, in the flip-flop circuit according to the third embodiment, the first data retaining circuit 18A and the second data retaining circuit 20A are constituted by inverter circuits, but the first data reading circuit 17 of the master side element 100 and the second data reading circuit 19A of the slave side element 200 are the same as those in the flip-flop circuit according to the second embodiment. Therefore, the description about the first data reading circuit 17 and the second data reading circuit 19A will be omitted. On the other hand, the specific configurations of the inverters 2, 3, 10, 11, 21, 22 in the flip-flop circuit according to the third embodiment may be the same as those in the inverter circuit as shown in FIG. 26B explained above.

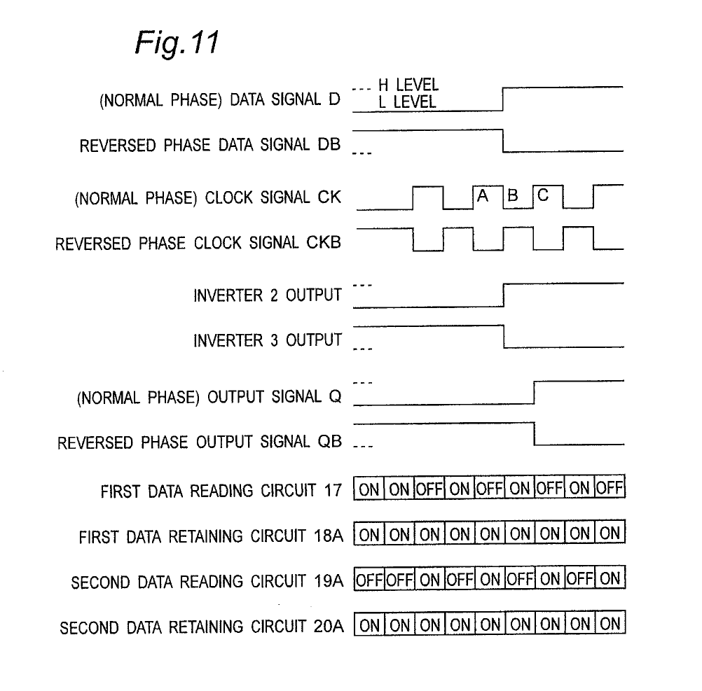

The operation of the flip-flop circuit according to the third embodiment having the above configuration will be explained with reference to FIG. 10 and FIG. 11. FIG. 11 is a timing chart illustrating operation of the flip-flop circuit according to the third embodiment.

The timing chart of FIG. 11 illustrates the (normal phase) data signal D, the reversed phase data signal DB, the (normal phase) clock signal CK, the reversed phase clock signal CKB, the output of the inverter 2 in the first data retaining circuit 18A, the output of the inverter 3 in the first data retaining circuit 18A, the (normal phase) output signal Q, the reversed phase output signal QB, ON/OFF operational state of the first data reading circuit 17 of the master side element 100, ON/OFF operational state of the first data retaining circuit 18A of the master side element 100, ON/OFF operational state of the second data reading circuit 19A of the slave side element 200, and ON/OFF operational state of the second data retaining circuit 20 of the slave side element 200.

As shown in FIG. 11, regardless of timing of the clock signal CK, the first data retaining circuit 18A of the master side element 100 and the second data retaining circuit 20A of the slave side element 200 are always in ON state.

First, the operation will be explained when the clock signal CK is at L level.

When the clock signal CK is at L level, the reversed phase clock signal CKB is input to the gate terminal of the NMOS 6 in the first data reading circuit 17. Accordingly, the gate voltage thereof is at H level. On the other hand, the clock signal CK is input to the gate terminals of the PMOS 4 and the PMOS 8. Accordingly, the gate voltage thereof is at L level. Therefore, the first data reading circuit 17 of the master side element 100 is in ON state. It should be noted that the first data retaining circuit 18A of the master side element 100 is always in ON state.

When the clock signal CK is at L level, the clock signal CK is input to the gate terminal of the NMOS 16 in the second data retaining circuit 19A. Accordingly, the gate voltage is at L level. Therefore, the second data retaining circuit 19A of the slave side element 200 is at OFF state. It should be noted that the second data retaining circuit 20A of the slave side element 200 is always in ON state.

As described above, when the clock signal CK is at L level, the first data reading circuit 17 of the master side element 100 is in ON state. Accordingly, the data signal D and the reversed phase data signal DB input from the input terminals are read, and the states of the data signal D and the reversed phase data signal DB are reflected in the output of the inverter 2 and the output of the inverter 3, i.e., input/output of the first data retaining circuit 18A of the master side element 100.

When the clock signal CK is at L level, the second data reading circuit 19A of the slave side element 200 is in OFF state. However, the second data retaining circuit 20A of the slave side element 200 is in ON state. Accordingly, the slave side element 200 retains and outputs the output signal Q and the reversed phase output signal QB output by the second data reading circuit 19A of the slave side element 200 at a previous time in which the clock signal CK was at H level.

As shown in FIG. 11, the (normal phase) data signal D was at L level before the time A of the clock signal CK (rise), but is at H level after the time B (fall). Therefore, at the time B, the first data reading circuit 17 of the master side element 100 is in ON state, which changes the output of the inverter 2 to H level, and changes the output of the inverter 3 to L level in the first data retaining circuit 18A.

Subsequently, the operation will be explained when the clock signal CK is at H level.

When the clock signal CK is at H level, the reversed phase clock signal CKB is input to the gate terminal of the NMOS 6 of the first data reading circuit 17 in the master side element 100. Accordingly, the gate voltage thereof is at L level. The clock signal CK is input to the gate terminal of each of the PMOS 4 and the PMOS 8. Accordingly, the gate voltage thereof is at H level. Therefore, the first data reading circuit 17 in the master side element 100 is in OFF state.

When the clock signal CK is at H level, the clock signal CK is input to the gate terminal of the NMOS 16 of the second data retaining circuit 19A in the slave side element 200. Accordingly, the gate voltage thereof is at H level. Therefore, the second data retaining circuit 19A of the slave side element 200 is in ON state.

As described above, when the clock signal CK is at H level, the first data reading circuit 17 of the master side element 100 is in OFF state, but the first data retaining circuit 18A of the master side element 100 is in ON state. Accordingly, the first data retaining circuit 18A retains the output of the inverter 2 and the output of the inverter 3 output by the first data reading circuit 17 of the master side element 100 at a previous time in which the clock signal CK was at L level.

When the clock signal CK is at H level, the second data reading circuit 19A of the slave side element 200 is in ON state. Accordingly, the output signals of the inverter 2 and the inverter 3 are read, and are reflected in the output (QB) of the inverter 11 and the output (Q) of the inverter 10, i.e., input/output of the second data retaining circuit 20A of the slave side element 200.

As shown in FIG. 11, the output of the inverter 2 was at L level before the time A of the clock signal CK (rise), but is at H level after the time B (fall). Therefore, at the time C, the second data reading circuit 19A of the slave side element 200 is in ON state, which changes the output (Q) of the inverter 10 to H level and changes the output (QB) of the inverter 11 to L level in the second data retaining circuit 20A.

According to the above operation, the flip-flop circuit according to the third embodiment is achieved.

As described above, compared with the conventional flip-flop circuit, the flip-flop circuit according to the third embodiment is configured such that the second data reading circuit 19A of the slave side element 200 is constituted by the inverter circuit having the inverter 21 and the inverter 22. Therefore, in the flip-flop circuit according to the third embodiment, the inverters 21, 22 constituting the inverter circuit flow a consumption current only in a time in which, for example, the PMOS 31 and the NMOS 32 as shown in FIG. 26B operate in the saturation characteristic region, and flow only little consumption current while they operate in the linear characteristic region. As a result, the flip-flop circuit according to the third embodiment achieves an effect of reducing the average consumption current.

Further, in the flip-flop circuit according to the third embodiment, the second data reading circuit 19A of the slave side element 200 is constituted by the inverter circuit including the inverter 21 and the inverter 22. Therefore, the flip-flop circuit according to the third embodiment achieves the following effects. The gain, i.e., variation of output voltage in response to variation of input voltage is increased. The operation speed of the output signal in response to the input signal is improved. In addition, the maximum operating frequency is improved.

### Fourth Embodiment

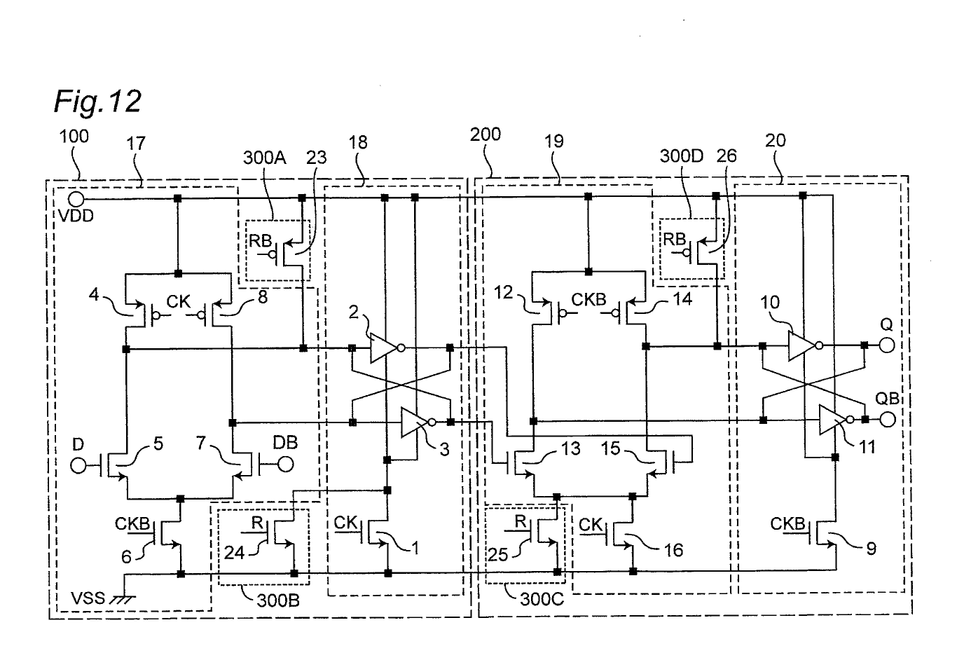

FIG. 12 is a circuit diagram illustrating a configuration of a flip-flop circuit according to the fourth embodiment of the present invention. In the flip-flop circuit according to the fourth embodiment, constituent elements having substantially the same functions and configurations as those in the flip-flop circuit according to the first embodiment as explained above are denoted with the same reference numerals, and the description thereabout is omitted.

As shown in FIG. 12, the flip-flop circuit according to the fourth embodiment includes the master side element 100 and the slave side element 200 in the same manner as the flip-flop circuit according to the first embodiment explained above. The master side element 100 includes the first data reading circuit 17 and the first data retaining circuit 18, and the slave side element 200 includes the second data reading circuit 19 and the second data retaining circuit 20.

In the flip-flop circuit according to the fourth embodiment, the first data reading circuit 17 and the second data reading circuit 19 are constituted by differential circuits, and the first data retaining circuit 18 and the second data retaining circuit 20 are constituted by inverter circuits, in the same manner as the flip-flop circuit according to the first embodiment as shown in FIG. 2. Further, drive power supplies of the first data retaining circuit 18 and the second data reading circuit 19 are controlled by a clock signal CK given from the outside. Drive power supplies of the first data reading circuit 17 and the second data retaining circuit 20 are controlled by a reversed phase clock signal CKB.

The flip-flop circuit according to the fourth embodiment is different from the flip-flop circuit according to the first embodiment in that the master side element 100 and the slave side element 200 are respectively arranged with reset devices (300A, 300B, 300C, 300D).

As shown in FIG. 12, the first reset circuit 300A is constituted by a PMOS 23, the second reset circuit 300B is constituted by an NMOS 24, the third reset circuit 300C is constituted by an NMOS 25, and the fourth reset circuit 300D is constituted by a PMOS 26. A reset signal (hereinafter referred to as reversed phase reset signal) RB having a phase opposite to a normal phase reset signal is input to the gate terminals of the PMOS 23 of the first reset circuit 300A and the PMOS 26 of the fourth reset circuit 300D. A reset signal (hereinafter simply referred to as reset signal) R, i.e., a reset signal having a normal phase, is input to the NMOS 24 of the second reset circuit 300B and the NMOS 25 of the third reset circuit 300C.

As described above, in the flip-flop circuit according to the fourth embodiment, the master side element 100 and the slave side element 200 are respectively arranged with reset devices (300A, 300B, 300C, 300D). Therefore, a reset function is added to the flip-flop circuit, and intermittent operation is enabled.

Subsequently, the reset devices (300A, 300B, 300C, 300D) of the flip-flop circuit according to the fourth embodiment will be explained. The reset devices (300A, 300B, 300C, 300D) distinguish the fourth embodiment from the flip-flop circuit according to the first embodiment.

In the first reset circuit 300A, the output end of the inverter 3, i.e., the output end of the maser side element 100, is connected to the high potential side power supply VDD via the PMOS 23. In the second reset circuit 300B, the drain terminal and the source terminal of the NMOS 1 of the first data retaining circuit 18 in the master side element 100 are connected to the drain terminal and the source terminal of the NMOS 24, respectively.

In the third reset circuit 300C, the drain terminal and the source terminal of the NMOS 16 of the second data reading circuit 19 in the slave side element 200 are connected to the drain terminal and the source terminal of the NMOS 25, respectively. In the fourth reset circuit 300D, the output end of the inverter 11, i.e., the output terminal of the reversed phase output signal QB of the flip-flop circuit, is connected to the high potential side power supply VDD via the PMOS 26.

In the reset devices (300A, 300B, 300C, 300D) connected as described above, the (normal phase) reset signal R is input to the gate terminal of each of the NMOS 24 and the NMOS 25, and the reversed phase reset signal RB is input to the gate terminal of each of the PMOS 23 and the PMOS 26. Thus, reset operation is performed.

Subsequently, the reset operation in the flip-flop circuit according to the fourth embodiment having the above configuration will be explained.

In the flip-flop circuit according to the fourth embodiment, the reset signal R at H level is input the gate terminal of each of the NMOS 24, 25, and the reversed phase reset signal RB at L level is input to the gate terminal of each of the PMOS 23, 26. Accordingly, the output voltage of the (normal phase) output signal Q is at L level, and the output voltage of the reversed phase output signal QB is at H level. As described above, the reset signal R and the reversed phase reset signal RB are input to the NMOS 24, 25 and the PMOS 23, 26, whereby the output ends of the inverters 2, 10 are fixed at L level, and the output ends of the inverters 3, 11 are fixed at H level, so that initial values can be set to the outputs of the first and second data retaining circuits 18, 20.

In particular, in the flip-flop circuit according to the fourth embodiment, when the clock signal CK and the reversed phase clock signal CKB are not input, all of the first data retaining circuit 18 of the master side element 100, the second data reading circuit 19 of the slave side element 200, and the second data retaining circuit 20 of the slave side element 200 are in halted state. At this occasion, the reset function is activated to perform reset operation, whereby each circuit is brought to operational state, so that initial values can be set to the outputs of the first and second data retaining circuits 18, 20.

The flip-flop circuit according to the fourth embodiment as shown in FIG. 12 is a circuit configuration that can achieve the effects of the flip-flop circuit according to the first embodiment and can achieve the reset operation.

The flip-flop circuit according to the fourth embodiment having the above configuration includes the reset function added to the flip-flop circuit according to the first embodiment. Even when the clock signal CK, the reversed phase clock signal CKB, the data signal D, and the reversed phase data signal DB are input when the power supply is turned off and then turned on again, initial values can be set to the outputs of the first and second data retaining circuits 18, 20.

### Fifth Embodiment

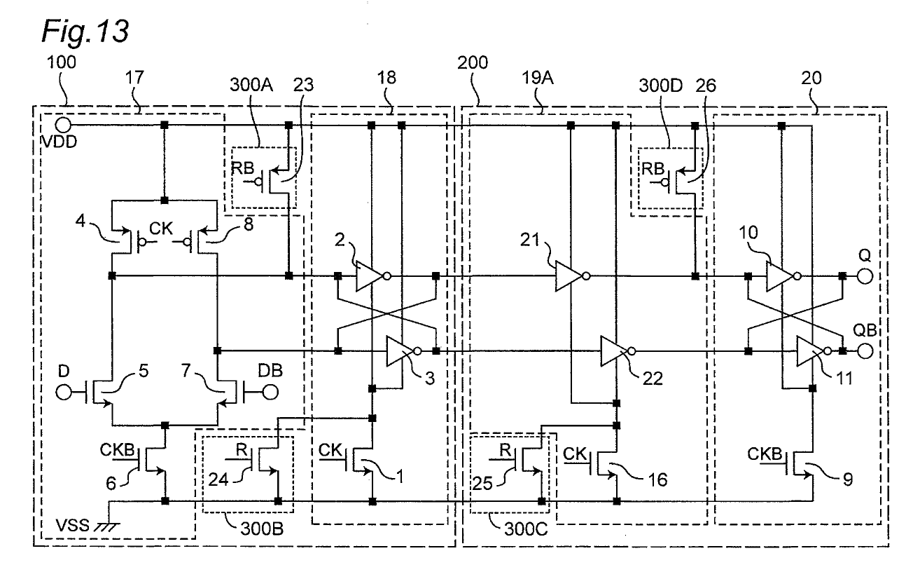

FIG. 13 is a circuit diagram illustrating a configuration of a flip-flop circuit according to the fifth embodiment of the present invention. In the flip-flop circuit according to the fifth embodiment, constituent elements having substantially the same functions and configurations as those in the flip-flop circuit according to the first and second embodiments as explained above are denoted with the same reference numerals, and the description thereabout is omitted.

As shown in FIG. 13, the flip-flop circuit according to the fifth embodiment includes the master side element 100 and the slave side element 200 in the same manner as the flip-flop circuit according to the second embodiment as shown in FIG. 8 explained above. The master side element 100 includes the first data reading circuit 17 and the first data retaining circuit 18, and the slave side element 200 includes the second data reading circuit 19A and the second data retaining circuit 20.

In the flip-flop circuit according to the fifth embodiment, the first data reading circuit 17 is constituted by a differential circuit, and the first data retaining circuit 18, the second data reading circuit 19A, and the second data retaining circuit 20 are constituted by inverter circuits, in the same manner as the flip-flop circuit according to the second embodiment as shown in FIG. 8. Further, drive power supplies of the first data retaining circuit 18 and the second data reading circuit 19A are controlled by a clock signal CK given from the outside. Drive power supplies of the first data reading circuit 17 and the second data retaining circuit 20 are controlled by a reversed phase clock signal CKB.

The flip-flop circuit according to the fifth embodiment is different from the flip-flop circuit according to the second embodiment in that the master side element 100 and the slave side element 200 are respectively arranged with reset devices (300A, 300B, 300C, 300D).

As shown in FIG. 13, the first reset circuit 300A is constituted by the PMOS 23, the second reset circuit 300B is constituted by the NMOS 24, the third reset circuit 300C is constituted by the NMOS 25, and the fourth reset circuit 300D is constituted by the PMOS 26. The reversed phase reset signal RB is input to the gate terminals of the PMOS 23 of the first reset circuit 300A and the PMOS 26 of the fourth reset circuit 300D. The (normal phase) reset signal R is input to the gate terminals of the NMOS 24 of the second reset circuit 300B and the NMOS 25 of the third reset circuit 300C.

As described above, in the flip-flop circuit according to the fifth embodiment, the master side element 100 and the slave side element 200 are respectively arranged with reset devices (300A, 300B, 300C, 300D). Therefore, a reset function is added to the flip-flop circuit, and intermittent operation is enabled.

Subsequently, the reset devices (300A, 300B, 300C, 300D) of the flip-flop circuit according to the fifth embodiment will be explained. The reset devices (300A, 300B, 300C, 300D) distinguish the fifth embodiment from the flip-flop circuit according to the second embodiment as shown in FIG. 8.

In the first reset circuit 300A, the output end of the inverter 3, i.e., the output end of the maser side element 100, is connected to the high potential side power supply VDD via the PMOS 23. In the second reset circuit 300B, the drain terminal and the source terminal of the NMOS 1 of the first data retaining circuit 18 in the master side element 100 are connected to the drain terminal and the source terminal of the NMOS 24, respectively.

In the third reset circuit 300C, the drain terminal and the source terminal of the NMOS 16 of the second data reading circuit 19A in the slave side element 200 are connected to the drain terminal and the source terminal of the NMOS 25, respectively. In the fourth reset circuit 300D, the output end of the inverter 11, i.e., the output terminal of the reversed phase output signal QB of the flip-flop circuit, is connected to the high potential side power supply VDD via the PMOS 26.

In the reset devices (300A, 300B, 300C, 300D) connected as described above, the (normal phase) reset signal R is input to the gate terminal of each of the NMOS 24 and the NMOS 25, and the reversed phase reset signal RB is input to the gate terminal of each of the PMOS 23 and the PMOS 26. Thus, reset operation is performed.

Subsequently, the reset operation in the flip-flop circuit according to the fifth embodiment having the above configuration will be explained.

In the flip-flop circuit according to the fifth embodiment, the reset signal R at H level is input the gate terminal of each of the NMOS 24, 25, and the reversed phase reset signal RB at L level is input to the gate terminal of each of the PMOS 23, 26. Accordingly, the output voltage of the (normal phase) output signal Q is at L level, and the output voltage of the reversed phase output signal QB is at H level. As described above, the reset signal R and the reversed phase reset signal RB are input to the NMOS 24, 25 and the PMOS 23, 26, whereby the output ends of the inverters 2, 10 are fixed at L level, and the output ends of the inverters 3, 11 are fixed at H level, so that initial values can be set to the outputs of the first and second data retaining circuits 18, 20.

In particular, in the flip-flop circuit according to the fifth embodiment, when the clock signal CK and the reversed phase clock signal CKB are not input, all of the first data retaining circuit 18 of the master side element 100, the second data reading circuit 19A of the slave side element 200, and the second data retaining circuit 20 of the slave side element 200 are in halted state. At this occasion, the reset function is activated to perform reset operation, whereby each circuit is brought to operational state, so that initial values can be set to the outputs of the first and second data retaining circuits 18, 20.

The flip-flop circuit according to the fifth embodiment as shown in FIG. 13 is a circuit configuration that can achieve the effects of the flip-flop circuit according to the first and second embodiments and can achieve the reset operation.

The flip-flop circuit according to the fifth embodiment having the above configuration includes the reset function added to the flip-flop circuit according to the second embodiment. Even when the clock signal CK, the reversed phase clock signal CKB, the data signal D, and the reversed phase data signal DB are input when the power supply is turned off and then turned on again, initial values can be set to the outputs of the first and second data retaining circuits 18, 20.

### Sixth Embodiment

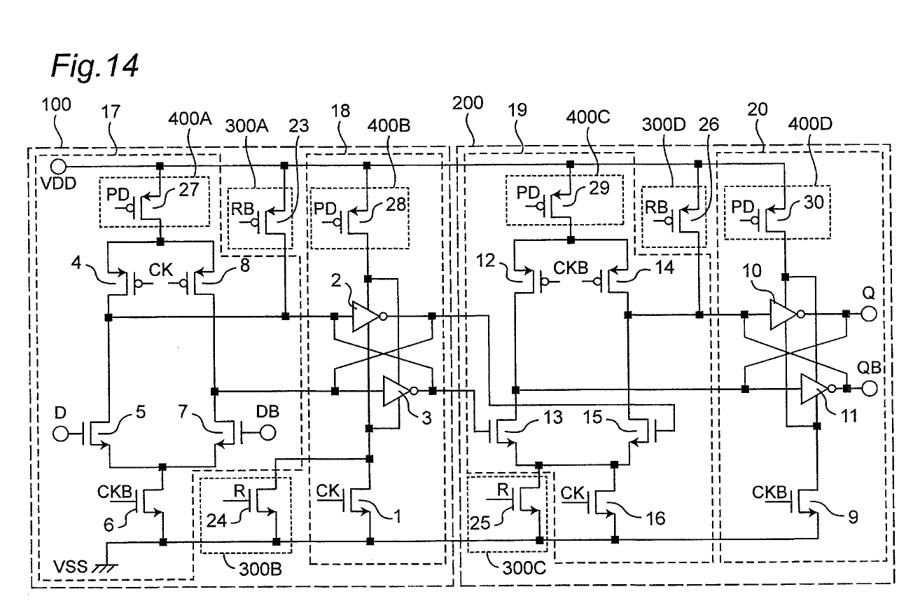

FIG. 14 is a circuit diagram illustrating a configuration of a flip-flop circuit according to the sixth embodiment of the present invention. In the flip-flop circuit according to the sixth embodiment, constituent elements having substantially the same functions and configurations as those in the flip-flop circuit according to the first to fifth embodiments as explained above are denoted with the same reference numerals, and the description thereabout is omitted.

As shown in FIG. 14, the flip-flop circuit according to the sixth embodiment includes the master side element 100 and the slave side element 200 in the same manner as the fourth embodiment as shown in FIG. 12 explained above. The master side element 100 includes the first data reading circuit 17 and the first data retaining circuit 18, and the slave side element 200 includes the second data reading circuit 19 and the second data retaining circuit 20.

In the flip-flop circuit according to the sixth embodiment, the first data reading circuit 17 and the second data reading circuit 19 are constituted by differential circuits, and the first data retaining circuit 18 and the second data retaining circuit 20 are constituted by inverter circuits, in the same manner as the flip-flop circuit according to the fourth embodiment as shown in FIG. 12. Further, drive power supplies of the first data retaining circuit 18 and the second data reading circuit 19 are controlled by a clock signal CK given from the outside. Drive power supplies of the first data reading circuit 17 and the second data retaining circuit 20 are controlled by a reversed phase clock signal CKB.

The flip-flop circuit according to the sixth embodiment is different from the flip-flop circuit according to the fourth embodiment in that the master side element 100 and the slave side element 200 are respectively arranged with reset devices (300A, 300B, 300C, 300D).

The flip-flop circuit according to the sixth embodiment is different from the flip-flop circuit according to the fourth embodiment in that the first data reading circuit 17, the first data retaining circuit 18, the second data reading circuit 19, and the second data retaining circuit 20 are respectively arranged with power-down devices (400A, 400B, 400C, 400D) for inputting a power-down signal PD for halting input of power supply.

As shown in FIG. 14, the first data reading circuit 17 is arranged with the first power-down circuit 400A, and the first power-down circuit 400A is constituted by a PMOS 27. The first data retaining circuit 18 is arranged with the second power-down circuit 400B, and the second power-down circuit 400B is constituted by a PMOS 28. The second data reading circuit 19 is arranged with the third power-down circuit 400C, and the third power-down circuit 400C is constituted by a PMOS 29. The second data retaining circuit 20 is arranged with the fourth power-down circuit 400D, and the fourth power-down circuit 400D is constituted by a PMOS 30. The power-down signal PD is input to the gate terminal of each of the PMOS 27, 28, 29, 30 of the power-down devices (400A, 400B, 400C, 400D).

As described above, the flip-flop circuit according to the sixth embodiment includes the PMOS 27, 28, 29, 30 as the power-down devices (400A, 400B, 400C, 400D), which add a power-down function to the flip-flop circuit to stop operation of each circuit of the first data reading circuit 17, the first data retaining circuit 18, the second data reading circuit 19, and the second data retaining circuit 20. Therefore, the flip-flop circuit according to the sixth embodiment can achieve intermittent operation by stopping operation of each circuit of the first data reading circuit 17, the first data retaining circuit 18, the second data reading circuit 19, and the second data retaining circuit 20, without turning off the power supply for the entire flip-flop circuit.

Subsequently, the reset devices (400A, 400B, 400C, 400D) of the flip-flop circuit according to the sixth embodiment will be explained. The reset devices (400A, 400B, 400C, 400D) distinguish the sixth embodiment from the flip-flop circuit according to the fourth embodiment.

In the first power-down circuit 400A, the source terminals of the PMOS 4 and the PMOS 8 of the first data reading circuit 17 of the master side element 100 are connected to the high potential side power supply VDD via the PMOS 27. In the second power-down circuit 400B, the power supply ends of the inverters 2, 3 of the first data retaining circuit 18 of the master side element 100 are connected to the high potential side power supply VDD via the PMOS 28. In the third power-down circuit 400C, the source terminals of the PMOS 12 and the PMOS 14 of the second data reading circuit 19 of the slave side element 200 are connected to the high potential side power supply VDD via the PMOS 29. In the fourth power-down circuit 400D, the power supply ends of the inverters 10, 11 of the second data retaining circuit 20 of the slave side element 200 are connected to the high potential side power supply VDD via the PMOS 30.

Power-down operation is performed when the power-down signal PD is input to the gate terminal of each of the PMOS 27, 28, 29, 30 in the power-down devices (400A, 400B, 400C, 400D) connected as explained above.

Subsequently, the power-down operation of the flip-flop circuit according to the sixth embodiment having the configuration as described above will be explained.

In the flip-flop circuit according to the sixth embodiment, the power-down signal PD at H level is input to the gate terminal of each of the PMOS 27, 28, 29, 30 under the condition that the flip-flop circuit is not in reset state. Accordingly, transistors in OFF state are interposed between the high potential side power supply VDD and each of the constituent elements. As a result, the operation of the flip-flop circuit stops.

The flip-flop circuit according to the sixth embodiment having the above configuration includes the power-down function added to the flip-flop circuit according to the fourth embodiment. Therefore, the flip-flop circuit according to the sixth embodiment can achieve not only the effects of the flip-flop circuit according to the fourth embodiment but also the effect of enabling intermittent operation by stopping operation of each constituent circuit of the first data reading circuit 17, the first data retaining circuit 18, the second data reading circuit 19, and the second data retaining circuit 20, without turning off the power supply.

In the above explanation, the flip-flop circuit according to the sixth embodiment includes the power-down function added to the flip-flop circuit according to the fourth embodiment. However, the present invention is not limited thereto. The power-down function may be added to the flip-flop circuit according to the first, second, and third embodiments.

### Seventh Embodiment

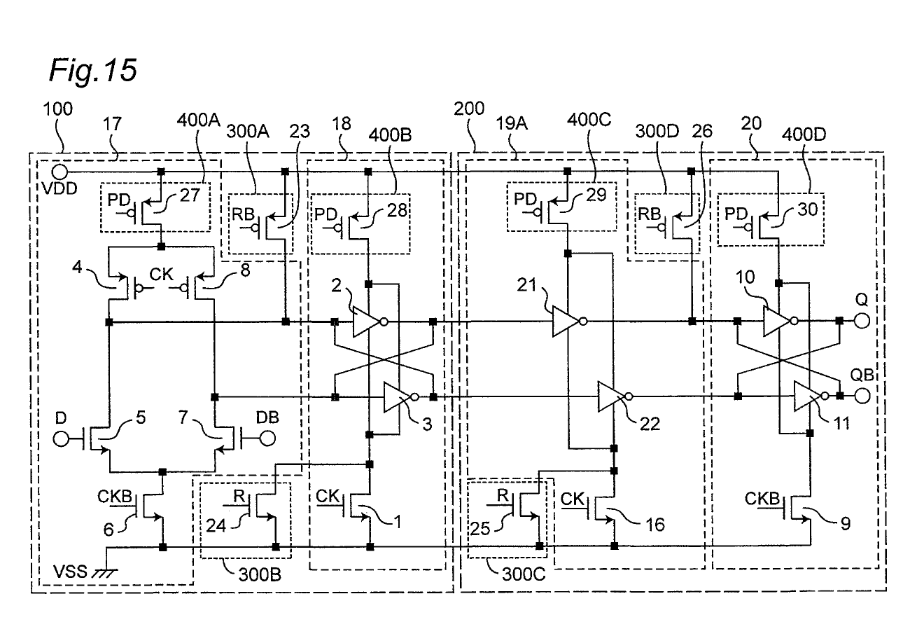

FIG. 15 is a circuit diagram illustrating a configuration of a flip-flop circuit according to the seventh embodiment of the present invention. In the flip-flop circuit according to the seventh embodiment, constituent elements having substantially the same functions and configurations as those in the flip-flop circuit according to the first to sixth embodiments as explained above are denoted with the same reference numerals, and the description thereabout is omitted.

As shown in FIG. 15, the flip-flop circuit according to the seventh embodiment includes the master side element 100 and the slave side element 200 in the same manner as the fifth embodiment as shown in FIG. 13 explained above. The master side element 100 includes the first data reading circuit 17 and the first data retaining circuit 18, and the slave side element 200 includes the second data reading circuit 19A and the second data retaining circuit 20.

In the flip-flop circuit according to the seventh embodiment, the first data reading circuit 17 is constituted by a differential circuit, and the first data retaining circuit 18, the second data reading circuit 19A, and the second data retaining circuit 20 are constituted by inverter circuits, in the same manner as the flip-flop circuit according to the fifth embodiment as shown in FIG. 13. Further, drive power supplies of the first data retaining circuit 18 and the second data reading circuit 19A are controlled by a clock signal CK given from the outside. Drive power supplies of the first data reading circuit 17 and the second data retaining circuit 20 are controlled by a reversed phase clock signal CKB.

Further, in the flip-flop circuit according to the seventh embodiment, the master side element 100 and the slave side element 200 are respectively arranged with the reset devices (300A, 300B, 300C, 300D) in the same manner as the flip-flop circuit according to the fifth embodiment explained above.

The flip-flop circuit according to the seventh embodiment is different from the flip-flop circuit according to the fifth embodiment in that the first data reading circuit 17, the first data retaining circuit 18, the second data reading circuit 19, and the second data retaining circuit 20 are respectively arranged with power-down devices (400A, 400B, 400C, 400D) for inputting a power-down signal PD for halting input of power supply.

As shown in FIG. 15, the first data reading circuit 17 is arranged with the first power-down circuit 400A, and the first power-down circuit 400A is constituted by the PMOS 27. The first data retaining circuit 18 is arranged with the second power-down circuit 400B, and the second power-down circuit 400B is constituted by the PMOS 28. The second data reading circuit 19 is arranged with the third power-down circuit 400C, and the third power-down circuit 400C is constituted by the PMOS 29. The second data retaining circuit 20 is arranged with the fourth power-down circuit 400D, and the fourth power-down circuit 400D is constituted by the PMOS 30. The power-down signal PD is input to the gate terminal of each of the PMOS 27, 28, 29, 30 of the power-down devices (400A, 400B, 400C, 400D).

As described above, the flip-flop circuit according to the seventh embodiment includes the PMOS 27, 28, 29, 30 as the power-down devices (400A, 400B, 400C, 400D), which add a power-down function to the flip-flop circuit to stop operation of each circuit of the first data reading circuit 17, the first data retaining circuit 18, the second data reading circuit 19A, and the second data retaining circuit 20. Therefore, the flip-flop circuit according to the seventh embodiment can achieve intermittent operation by stopping operation of each circuit of the first data reading circuit 17, the first data retaining circuit 18, the second data reading circuit 19A, and the second data retaining circuit 20, without turning off the power supply for the entire flip-flop circuit.

Subsequently, the power-down devices (400A, 400B, 4000, 400D) of the flip-flop circuit according to the seventh embodiment will be explained. The power-down devices (400A, 400B, 4000, 400D) distinguish the seventh embodiment from the flip-flop circuit according to the fifth embodiment.

In the first power-down circuit 400A, the source terminals of the PMOS 4 and the PMOS 8 of the first data reading circuit 17 of the master side element 100 are connected to the high potential side power supply VDD via the PMOS 27. In the second power-down circuit 400B, the power supply ends of the inverters 2, 3 of the first data retaining circuit 18 of the master side element 100 are connected to the high potential side power supply VDD via the PMOS 28. In the third power-down circuit 400C, the power supply ends of the inverters 21, 22 in the second data reading circuit 19A of the slave side element 200 are connected to the high potential side power supply VDD via the PMOS 29. In the fourth power-down devices 400D, the power supply end of each of the inverters 10, 11 in the second data retaining circuit 20 of the slave side element 200 is connected to the high potential side power supply VDD via the PMOS 30.

Power-down operation is performed when the power-down signal PD is input to the gate terminal of each of the PMOS 27, 28, 29, 30 in the power-down devices (400A, 400B, 400C, 400D) connected as explained above.

Subsequently, the power-down operation of the flip-flop circuit according to the seventh embodiment having the configuration as described above will be explained.

In the flip-flop circuit according to the seventh embodiment, the power-down signal PD at H level is input to the gate terminal of each of the PMOS 27, 28, 29, 30 under the condition that the flip-flop circuit is not in reset state. Accordingly, transistors in OFF state are interposed between the high potential side power supply VDD and each of the constituent elements. As a result, the operation of the flip-flop circuit stops.

The flip-flop circuit according to the seventh embodiment having the above configuration includes the power-down function added to the flip-flop circuit according to the fifth embodiment. Therefore, the flip-flop circuit according to the seventh embodiment can achieve not only the effects of the flip-flop circuit according to the fifth embodiment but also the effect of enabling intermittent operation by stopping operation without turning off the power supply.

### Eighth Embodiment

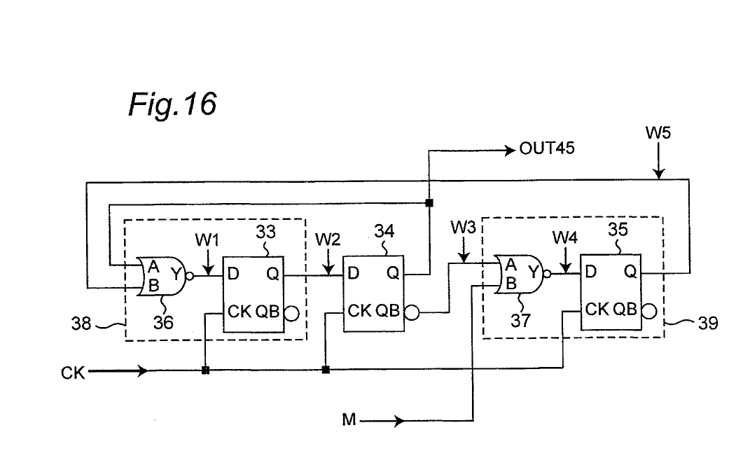

FIG. 16 is a block diagram illustrating a configuration of a one-quarter/one-fifth variable frequency dividing circuit according to the eighth embodiment of the present invention. The one-quarter/one-fifth variable frequency dividing circuit according to the eighth embodiment is a frequency dividing circuit capable of switching dividing ratio to 1/4 or 1/5. The eighth embodiment is an example of one-quarter/one-fifth variable frequency dividing circuit using the flip-flop circuit according to the first to seventh embodiments explained above.

In FIG. 16, reference numerals 33, 34, 35 denote the flip-flop circuits according to any one of the first to seventh embodiments. Reference numerals 36, 37 denote logical circuits NOR. The logical circuit NOR 36 and the flip-flop circuit 33 constitute a first block 38, and an output (W1) of the logical circuit NOR 36 is input as a data signal (D) of the flip-flop circuit 33. The logical circuit NOR 37 and the flip-flop circuit 35 constitute a second block 39. An output (W4) of the logical circuit NOR 37 is input as a data signal (D) of the flip-flop circuit 35.

A signal of an output terminal OUT 45 is an output of the one-quarter/one-fifth variable frequency dividing circuit according to the eighth embodiment. A dividing switching signal M is a signal input for switching and setting dividing operation to either one-quarter/one-fifth.

In FIG. 16, “W1” denotes an output of the logical circuit NOR 36, “W2” denotes an output (Q) of the flip-flop circuit 33, “W3” denotes a reversed phase output (QB) of the flip-flop circuit 34, “W4” denotes an output of the logical circuit NOR 37, and “W5” denotes an output (Q) of the flip-flop circuit 35. In the logical circuit NOR 36, 37, “A” denotes one of input terminals, “B” denotes the other of input terminals, and “Y” denotes an output terminal. In the flip-flop circuits 33, 34, as shown in FIG. 16, “CK” denotes an input terminal of a normal phase clock signal, “D” denotes an input terminal of a normal phase data signal, “Q” denotes an output terminal of a normal phase output signal, and “QB” denotes an output terminal of a reversed phase output signal.

In the below explanation, “CK”, “D”, “Q”, and “QB” are assumed to be terminals for inputting/outputting for the flip-flop circuit.

Subsequently, a configuration of one-quarter/one-fifth variable frequency dividing circuit according to the eighth embodiment will be explained.

The normal phase output terminal Q of the flip-flop circuit 33 is connected to the normal phase data input terminal D of the flip-flop 34. The normal phase output terminal Q of the flip-flop circuit 34 serves as the output terminal OUT 45 of the one-quarter/one-fifth variable frequency dividing circuit according to the eighth embodiment, and is connected to the input terminal A of the logical circuit NOR 36. The reversed phase output terminal QB of the flip-flop circuit 34 is connected to the input terminal A of the logical circuit NOR 37. The output terminal Y of the logical circuit NOR 37 is connected to the normal phase data input terminal D of the flip-flop circuit 35. The normal phase output terminal Q of the flip-flop circuit 35 is connected to the input terminal B of the logical circuit NOR 36. The output terminal Y of the logical circuit NOR 36 is connected to the normal phase data input terminal D of the flip-flop circuit 33. The normal phase clock signal is input to the clock signal input terminals CK of the flip-flop circuit 33, the flip-flop circuit 34, and the flip-flop circuit 35, and the dividing switching signal M is input to the input terminal B of the logical circuit NOR 37. Thus, the one-quarter/one-fifth dividing operations are switched.

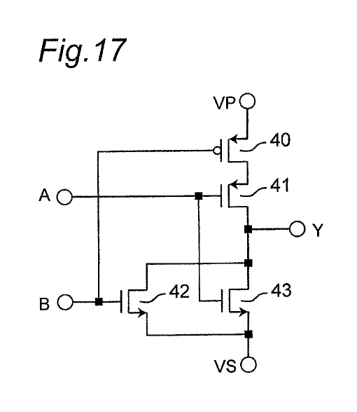

FIG. 17 is a circuit diagram illustrating specific configurations of the logical circuits 36, 37 used in the one-quarter/one-fifth variable frequency dividing circuit according to the eighth embodiment.

In FIG. 17, reference numerals 40, 41 denote PMOS, and reference numerals 42, 43 denote NMOS. “A” denotes one of input terminals of the logical circuit NOR. “B” denotes the other of the input terminals of the logical circuit NOR. “Y” denotes an output terminal of the logical circuit NOR. “VS” denotes an earthing end of the logical circuit NOR. “VP” denotes a power supply end of the logical circuit NOR.

In the logical circuit NOR as shown in FIG. 17, the source terminals and the drain terminals of the NMOS 42 and the NMOS 43 are connected with each other, and the source terminals thereof are connected to an earthing end VS. The drain terminals of the NMOS 42 and the NMOS 43 are connected to the output terminal Y, and are connected to the power supply end VP via the PMOS 41 and the PMOS 40. The gate terminals of the PMOS 40 and the NMOS 42 are connected with each other, and are connected to the input terminal B. The gate terminals of the PMOS 41 and the NMOS 43 are connected with each other, and are connected to the input terminal A.

The specific configuration of the flip-flop circuits 33, 34, 35 as shown in FIG. 16 may be any one of the flip-flop circuits as explained in the first to seventh embodiments explained above.

It should be noted that, in FIG. 16, the reversed phase data signal DB, the reversed phase clock signal CKB, the reset signal R, the reversed phase reset signal RB, and the power-down signal PD are omitted.

The operation of the one-quarter/one-fifth variable frequency dividing circuit according to the eighth embodiment having the above configuration will be explained.

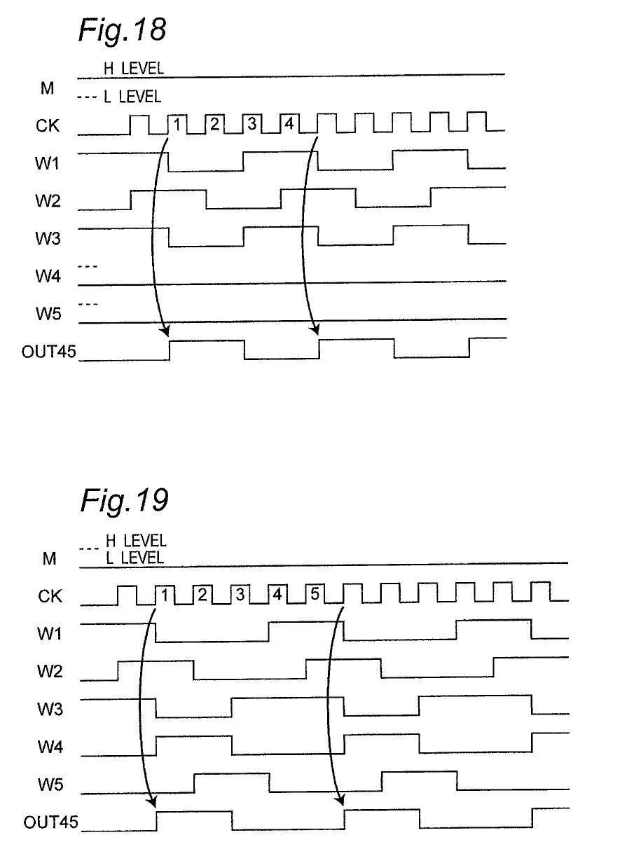

FIG. 18 is a timing chart illustrating operation of each unit during one-quarter dividing operation of the one-quarter/one-fifth variable frequency dividing circuit according to the eighth embodiment. FIG. 18 shows signal waveforms of each unit (M, CK, W1, W2, W3, W4, W5, OUT45) of the one-quarter/one-fifth variable frequency dividing circuit as shown in FIG. 16.

In FIG. 18, when the dividing switching signal M at H level is input, the output W4 of the logical circuit NOR 37 is fixed at L level, and the output W5 of the flip-flop circuit 35 is fixed at L level. Therefore, the logical circuit NOR 36 adopts, as an effective signal, a signal input to the input terminal A that is output from the output terminal OUT 45, and reverses and outputs the signal (W1). This output signal W1 is input to the data input terminal D of the flip-flop circuit 33, and is output as a signal (W2) delayed by one clock of the clock signal (CK) by the flip-flop circuit 33. The signal (W2) output by the flip-flop circuit 33 is input to the data input terminal D of the flip-flop circuit 34, and is output as a signal delayed by one clock of the clock signal (CK) from the output terminal OUT 45 by the flip-flop circuit 34.

As shown in FIG. 18, when the dividing switching signal M at H level is input, a signal obtained by dividing the clock signal (CK) into four is output to the output terminal OUT 45, as a result of the above operation.

FIG. 19 is a timing chart illustrating each unit during one-fifth dividing operation of the one-quarter/one-fifth variable frequency dividing circuit according to the eighth embodiment. FIG. 19 as well as FIG. 18 shows signal waveforms of each unit (M, CK, W1, W2, W3, W4, WS, OUT45) of the one-quarter/one-fifth variable frequency dividing circuit as shown in FIG. 16.

In FIG. 19, when the dividing switching signal M at L level is input, the logical circuit NOR 37 adopts, as an effective input, the signal of the output W3 from the reversed phase output terminal QB of the flip-flop circuit 34, and reverses and outputs the signal (W4). This output signal W4 is input to the data input terminal D of the flip-flop circuit 35, and is output as a signal (W5) delayed by one clock of the clock signal (CK) by the flip-flop circuit 35. The signal (W5) output from the flip-flop circuit 35 is input to the input terminal B of the logical circuit NOR 36. The logical circuit NOR 36 outputs a reversed signal (W1) of a logical OR of the signal (OUT45) input from the input terminal A and the signal (W5) input from the input terminal B. The signal (W1) output from the output terminal Y of the logical circuit NOR 36 is input to the data input terminal D of the flip-flop circuit 33, and is output as a signal (W2) delayed by one clock of the clock signal (CK) by the flip-flop circuit 33. The signal (W2) output from the flip-flop circuit 34 is input to the data input terminal D of the flip-flop circuit 34. Then, the flip-flop circuit 34 outputs the signal as a signal (OUT45) delayed by one clock of the clock signal (CK), and outputs the reversed output signal W3 to the input terminal A of the logical circuit NOR 37.

As shown in FIG. 19, when the dividing switching signal M at L level is input, a signal obtained by dividing the clock signal (CK) into five is output to the output terminal OUT 45, as a result of the above operation.

The one-quarter/one-fifth variable frequency dividing circuit according to the eighth embodiment having the above configuration and operation includes the flip-flop circuit according to the first to seventh embodiments achieving fast operation with a low power consumption. Therefore, the one-quarter/one-fifth variable frequency dividing circuit according to the eighth embodiment achieves a great effect of achieving fast operation with a low power consumption.

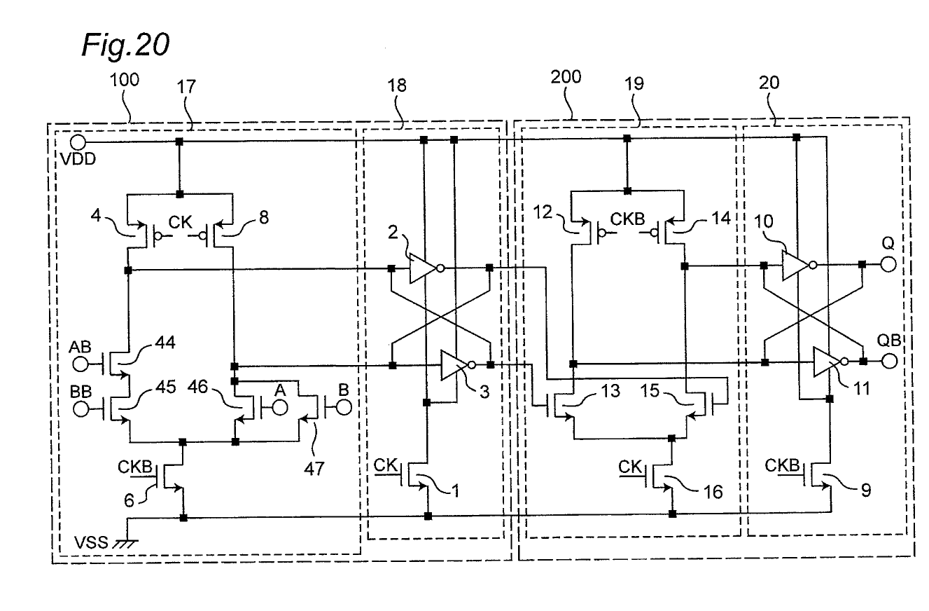

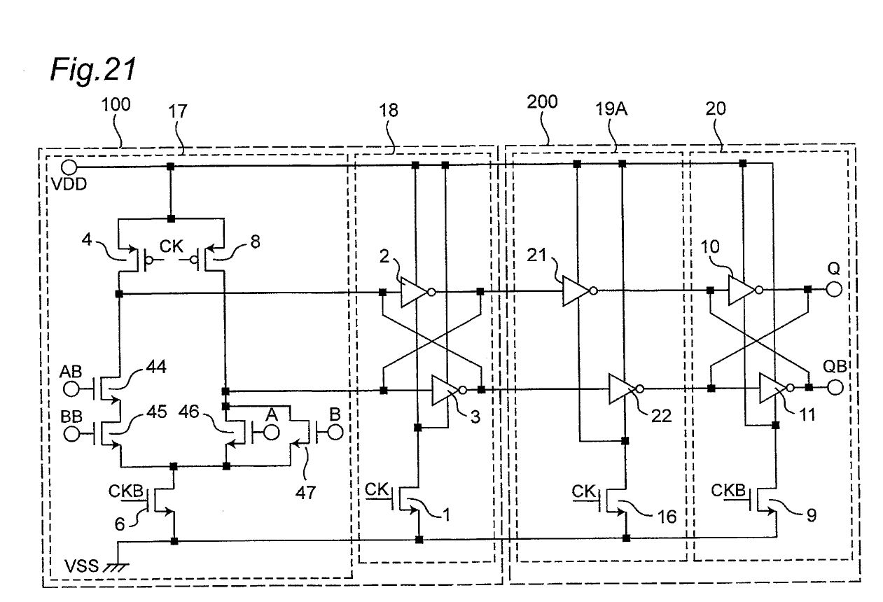

In the explanation about the one-quarter/one-fifth variable frequency dividing circuit according to the eighth embodiment as shown in FIG. 16, the first block 38 including the logical circuit NOR 36 and the flip-flop circuit 33 and the second block 39 including the logical circuit NOR 37 and the flip-flop circuit 35 are constituted by the logical circuit NOR as shown in FIG. 17 and the flip-flop circuits as explained in the first to seventh embodiments, for example. Alternatively, they may be constituted by circuit configurations as shown in FIG. 20 and FIG. 21 explained later.

The circuit configurations as shown in FIG. 20 and FIG. 21 will be hereinafter explained.

FIG. 20 is a circuit diagram illustrating a NOR function flip-flop circuit including one flip-flop circuit constituting the first block 38 having a circuit configuration in which the output terminal of the logical circuit NOR 36 is connected to the data input terminal of the flip-flop circuit 33 or the second block 39 having a circuit configuration in which the output terminal of the logical circuit NOR 37 is connected to the data input terminal of the flip-flop circuit 35 as shown in FIG. 16.

In FIG. 20, constituent elements having substantially the same functions and configurations as those in the flip-flop circuits according to the first to seventh embodiments explained above are denoted with the same reference numerals, and the description thereabout is omitted.

In FIG. 20, reference numerals 44,45,46,47 denote NMOS. Further, in FIG. 20, “A” denotes one of normal phase input terminals of the logical circuit NOR, “B” denotes the other of normal phase input terminals of the logical circuit NOR, “AB” denotes one of reversed phase input terminals for inputting a signal having a reversed phase of the signal input to the one of normal phase input terminals “A”, and “BB” denotes the other of reversed phase input terminals for inputting a signal having a reversed phase of the signal input to the other of normal phase input terminals “B”.

The NOR function flip-flop circuit as shown in FIG. 20 is different from the above-explained flip-flop circuit according to the first embodiment as shown in FIG. 2 in that the first data reading circuit 17 of the master side element 100 is arranged with the NMOS 44, the NMOS 45, the NMOS 46, and the NMOS 47, and the function of the logical circuit NOR is added to the data reading circuit 17 of the master side element 100. Therefore, in the flip-flop circuit as shown in FIG. 20, the first data reading circuit 17 and the second data reading circuit 19 are constituted by differential circuits, and the first data retaining circuit 18 and the second data retaining circuit 20 are constituted by inverter circuits.

The difference of the NOR function flip-flop circuit as shown in FIG. 20 from the configuration of the flip-flop circuit according to the first embodiment will be hereinafter explained in detail.

The input end of the inverter 2 of the first data retaining circuit 18 is connected to the high potential side power supply VDD via the PMOS 4 driven by the (normal phase) clock signal CK in first data reading circuit 17. The input end of the inverter 2 is connected to the low potential side power supply VSS via the NMOS 6 driven by the reversed phase clock signal CKB and the NMOS 44 and the NMOS 45 connected in series in the first data reading circuit 17.

On the other hand, the input end of the inverter 3 is connected to the high potential side power supply VDD via the PMOS 8 driven by the (normal phase) clock signal in the first data reading circuit 17. The input end of the inverter 3 is connected to the low potential side power supply VSS via the NMOS 6 driven by the reversed phase clock signal CKB and the NMOS 46 and the NMOS 47 connected in parallel in the first data reading circuit 17.

The NOR function flip-flop circuit as shown in FIG. 20 having the above configuration performs the same operation as the first block 38 and the second block 39 in which the NOR output as shown in FIG. 16 is connected to the data input of the flip-flop circuit. Therefore, the one-quarter/one-fifth variable frequency dividing circuit according to the eighth embodiment can be formed of the flip-flop circuit as shown in FIG. 20, and the same effects can be achieved.

FIG. 21 is a circuit diagram illustrating a NOR function flip-flop circuit including one flip-flop circuit constituting the first block 38 having a circuit configuration in which the output terminal of the logical circuit NOR 36 is connected to the data input terminal of the flip-flop circuit 33 or the second block 39 having a circuit configuration in which the output terminal of the logical circuit NOR 37 is connected to the data input terminal of the flip-flop circuit 35 as shown in FIG. 16.

In FIG. 21, constituent elements having substantially the same functions and configurations as those in the flip-flop circuits according to the first to seventh embodiments explained above are denoted with the same reference numerals, and the description thereabout is omitted.

In FIG. 21, reference numerals 44, 45, 46, 47 denote NMOS, in the same manner as the above-explained NOR function flip-flop circuit of FIG. 20. Further, in FIG. 21, “A” denotes one of normal phase input terminals of the logical circuit NOR, “B” denotes the other of normal phase input terminals of the logical circuit NOR, “AB” denotes one of reversed phase input terminals for inputting a signal having a reversed phase of the signal input to the one of normal phase input terminals “A”, and “BB” denotes the other of reversed phase input terminals for inputting a signal having a reversed phase of the signal input to the other of normal phase input terminals “B”.

The NOR function flip-flop circuit as shown in FIG. 21 is different from the above-explained flip-flop circuit according to the second embodiment as shown in FIG. 8 in that the first data reading circuit 17 of the master side element 100 is arranged with the NMOS 44, the NMOS 45, the NMOS 46, and the NMOS 47, and the function of the logical circuit NOR is added to the data reading circuit 17 of the master side element 100. Therefore, in the flip-flop circuit as shown in FIG. 21, the first data reading circuit 17 is constituted by a differential circuit, and the first data retaining circuit 18, the second data reading circuit 19A, and the second data retaining circuit 20 are constituted by inverter circuits.

The difference of the NOR function flip-flop circuit as shown in FIG. 21 from the configuration of the flip-flop circuit according to the second embodiment will be hereinafter explained in detail.

The input end of the inverter 2 of the first data retaining circuit 18 is connected to the high potential side power supply VDD via the PMOS 4 driven by the (normal phase) clock signal CK in first data reading circuit 17. The input end of the inverter 2 is connected to the low potential side power supply VSS via the NMOS 6 driven by the reversed phase clock signal CKB and the NMOS 44 and the NMOS 45 connected in series in the first data reading circuit 17.

On the other hand, the input end of the inverter 3 is connected to the high potential side power supply VDD via the PMOS 8 driven by the (normal phase) clock signal in the first data reading circuit 17. The input end of the inverter 3 is connected to the low potential side power supply VSS via the NMOS 6 driven by the reversed phase clock signal CKB and the NMOS 46 and the NMOS 47 connected in parallel in the first data reading circuit 17.

The NOR function flip-flop circuit as shown in FIG. 21 having the above configuration performs the same operation as the first block 38 and the second block 39 in which the NOR output as shown in FIG. 16 is connected to the data input of the flip-flop circuit. Therefore, the one-quarter/one-fifth variable frequency dividing circuit according to the eighth embodiment can be formed of the flip-flop circuit as shown in FIG. 21, and the same effects can be achieved.

### Ninth Embodiment

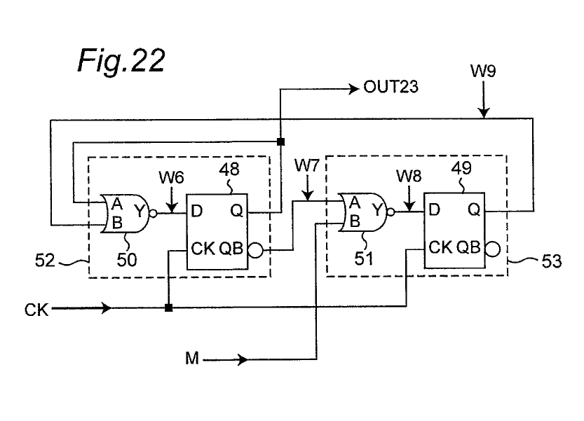

FIG. 22 is a block diagram illustrating a configuration of a one-half/one-third variable frequency dividing circuit according to the ninth embodiment of the present invention. The one-half/one-third variable frequency dividing circuit according to the ninth embodiment is a frequency dividing circuit capable of switching dividing ratio to 1/2 and 1/3. The ninth embodiment is an example of one-half/one-third variable frequency dividing circuit using the flip-flop circuit according to the first to seventh embodiments explained above.

In FIG. 22, reference numerals 48, 49 denote the flip-flop circuits according to any one of the first to seventh embodiments. Reference numerals 50, 51 denote logical circuits NOR. The logical circuit NOR 50 and the flip-flop circuit 48 constitute a first block 52, and an output (W6) of the logical circuit NOR 50 is input as a data signal (D) of the flip-flop circuit 48. The logical circuit NOR 51 and the flip-flop circuit 49 constitute a second block 53. An output (W8) of the logical circuit NOR 51 is input as a data signal (D) of the flip-flop circuit 49.

A signal of an output terminal OUT23 is an output of the one-half/one-third variable frequency dividing circuit according to the ninth embodiment. A dividing switching signal M is a signal input for switching and setting dividing operation to either one-half/one-third.

In FIG. 22, “W6” denotes an output of the logical circuit NOR 50, “W7” denotes a reversed phase output (QB) of the flip-flop circuit 48, “W8” denotes an output of the logical circuit NOR 51, and “W9” denotes an output (Q) of the flip-flop circuit 49. In the logical circuit NOR 50, 51, “A” denotes one of input terminals, “B” denotes the other of input terminals, and “Y” denotes an output terminal. In the flip-flop circuits 48, 49 as shown in FIG. 22, “CK” denotes an input terminal of a normal phase clock signal, “D” denotes an input terminal of a normal phase data signal, “Q” denotes an output terminal of a normal phase output signal, “QB” denotes an output terminal of a reversed phase output signal.

In the below explanation, “CK”, “D”, “Q”, and “QB” are assumed to be terminals for inputting/outputting for the flip-flop circuit.

Subsequently, a configuration of one-half/one-third variable frequency dividing circuit according to the ninth embodiment will be explained.

The normal phase output terminal Q of the flip-flop circuit 48 serves as the output terminal OUT 23 of the one-half/one-third variable frequency dividing circuit according to the ninth embodiment, and is connected to the input terminal A of the logical circuit NOR 50. The reversed phase output terminal QB of the flip-flop circuit 48 is connected to the input terminal A of the logical circuit NOR 51. The output terminal Y of the logical circuit NOR 51 is connected to the normal phase data input terminal D of the flip-flop circuit 49. The normal phase output terminal Q of the flip-flop circuit 49 is connected to the input terminal B of the logical circuit NOR 50. The output terminal Y of the logical circuit. NOR 50 is connected to the normal phase data input terminal D of the flip-flop circuit 48. The normal phase clock signal is input to the clock signal input terminals CK of the flip-flop circuit 48 and the flip-flop circuit 49, and the dividing switching signal M is input to the input terminal B of the logical circuit NOR 51. Thus, the one-half/one-third dividing operations are switched.

The specific configurations of the logical circuits 50, 51 used in the one-half/one-third variable frequency dividing circuit according to the ninth embodiment as shown in FIG. 22 are the same as those shown in FIG. 17 explained in the eighth embodiment. The specific configuration of the flip-flop circuits 48, 49 used in the one-half/one-third variable frequency dividing circuit according to the ninth embodiment may be any one of the flip-flop circuits as explained in the first to seventh embodiments explained above.

It should be noted that, in FIG. 22 the reversed phase data signal DB, the reversed phase clock signal CKB, the reset signal R, the reversed phase reset signal RB, and the power-down signal PD are omitted.

The operation of the one-half/one-third variable frequency dividing circuit according to the ninth embodiment having the above configuration will be explained.

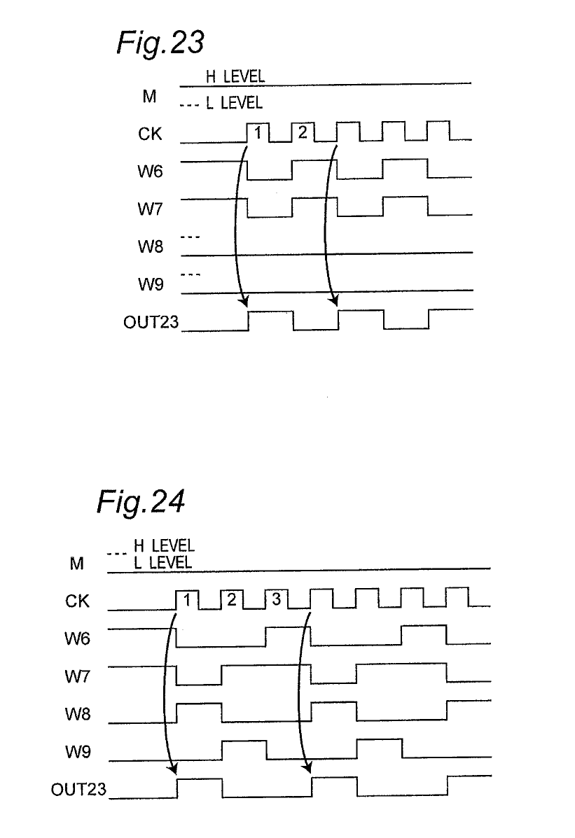

FIG. 23 is a timing chart illustrating operation of each unit during one-half dividing operation of the one-half/one-third variable frequency dividing circuit according to the ninth embodiment. FIG. 22 shows signal waveforms of each unit (M, CK, W6, W7, W8, W9, OUT23) of the one-half/one-third variable frequency dividing circuit as shown in FIG. 22.

In FIG. 23, when the dividing switching signal M at H level is input, the output W8 of the logical circuit NOR 51 is fixed at L level, and the output W9 of the flip-flop circuit 49 is fixed at L level. Therefore, the logical circuit NOR 50 adopts, as an effective signal, a signal input to the input terminal A that is output from the output terminal OUT 23, and reverses and outputs the signal (W6). This output signal W6 is input to the data input terminal D of the flip-flop circuit 48, and is output from the output terminal OUT 23 as a signal delayed by one clock of the clock signal (CK) by the flip-flop circuit 48.

As shown in FIG. 23, when the dividing switching signal M at H level is input, a signal obtained by dividing the clock signal (CK) into two is output to the output terminal OUT 23, as a result of the above operation.

FIG. 24 is a timing chart illustrating each unit during one-third dividing operation of the one-half/one-third variable frequency dividing circuit according to the ninth embodiment. FIG. 24 as well as FIG. 23 shows signal waveforms of each unit (M, CK, W6, W7, W8, W9, OUT23) of the one-half/one-third variable frequency dividing circuit according to the ninth embodiment as shown in FIG. 22.

In FIG. 24, when the dividing switching signal M at L level is input, the logical circuit NOR 51 adopts, as an effective signal, a signal of the output W7 from the reversed phase output terminal QB of the flip-flop circuit 48, and reverses and outputs the signal (W8). This output signal W8 is input to the data input terminal D of the flip-flop circuit 49, and is output as a signal (W9) delayed by one clock of the clock signal (CK) by the flip-flop 49. The output signal W9 is input to the input terminal B of the logical circuit NOR 50. The logical circuit NOR 50 outputs a reversed signal (W6) of a logical OR of the signal (OUT23) input from the input terminal A and the signal (W9) input from the input terminal B. The signal (W6) output from the output terminal Y of the logical circuit NOR 50 is input to the data input terminal D of the flip-flop circuit 48, and is output as a signal (OUT23) delayed by one clock of the clock signal (CK) by the flip-flop circuit 48. Further, the reversed output signal (W7) is output to the input terminal A of the logical circuit NOR 51.

As shown in FIG. 24, when the dividing switching signal M at L level is input, a signal obtained by dividing the clock signal (CK) into three is output to the output terminal OUT 23, as a result of the above operation.

The one-half/one-third variable frequency dividing circuit according to the ninth embodiment having the above configuration and operation includes the flip-flop circuit according to the first to seventh embodiments achieving fast operation with a low power consumption. Therefore, the one-half/one-third variable frequency dividing circuit according to the ninth embodiment achieves a great effect of achieving fast operation with a low power consumption.

In the one-half/one-third variable frequency dividing circuit according to the ninth embodiment as shown in FIG. 22, the first block 52 including the logical circuit NOR 50 and the flip-flop circuit 48 and the second block 53 including the logical circuit NOR 51 and the flip-flop circuit 49 can be constituted by the logical circuit NOR as shown in FIG. 17 in the eighth embodiment and the flip-flop circuits as explained in the first to seventh embodiments. Alternatively, the first block 52 and the second block 53 may be constituted by the NOR function flip-flop circuit having the circuit configurations as shown in FIG. 20 and FIG. 21 in the eighth embodiment explained above, and the same effects can be achieved.

As described above, the flip-flop circuit according to the present invention is configured such that connection is formed of the low potential side power supply via NMOS using the clock signal to drive the data retaining circuit of the master side element and the data retaining circuit of the slave side element. Accordingly, the ON/OFF state of operation of the data retaining circuit can be switched by the clock signal. As a result, in the present invention, the consumption current can be reduced, and the affect of the parasitic capacitance can be eliminated. Therefore, there are effects of the reduction of the consumption current in the flip-flop circuit and the improvement of the maximum operating frequency.

Further, in the present invention, the data reading circuit of the slave side element is constituted by the inviter circuit. Compared with a differential amplifier circuit, the inverter consumes a less current and provides a higher gain for changing the output in proportional to the input voltage. Therefore, the present invention achieves the following effects. The operation speed of the flip-flop circuit is improved. The consumption current is reduced. In addition, the maximum operating frequency is improved.

Further, in the flip-flop circuit according to the present invention, the reset function for fixing the output level is added to the output end of the data retaining circuit in the master side element and the output end of the data retaining circuit in the slave side element. In the present invention, the reset function may be added to the function for switching the ON/OFF state of operation of the data retaining circuit in the master side element and the data reading circuit constituted by the differential amplifier circuit in the slave side element. According to the flip-flop circuit of the present invention thus configured, the output level can be fixed upon the reset signal, and there is an effect of achieving a reset state without delay during intermittent operation.

Further, according to the present invention, the reset function for fixing the output level can be added to the output end of the data retaining circuit in the master side element and the output end of the data retaining circuit in the slave side element. In the present invention, the reset function may be added to the function for switching the ON/OFF state of operation of the data retaining circuit in the master side element and the data reading circuit constituted by the inverter in the slave side element. According to the flip-flop circuit of the present invention thus configured, the output level can be fixed upon the reset signal, and there is an effect of achieving a reset state without delay during intermittent operation.

Further, in the flip-flop circuit according to the present invention, transistors in OFF state may be interposed between the high potential side power supply VDD and each of the constituent elements including the data reading circuit and the data retaining circuit in the master side element and the data reading circuit and the data retaining circuit in the slave side element, whereby operation as the flip-flop circuit can be halted. According to the flip-flop circuit of the present invention thus configured, the power-down function can be added to the flip-flop circuit, and there is an effect of enabling intermittent operation by stopping operation without turning off the power supply.

The flip-flop circuit according to the present invention is effective for reducing power consumption as a constituent element of a radio communication semiconductor device used for a mobile communication apparatus and the like and improving the maximum operating frequency.

1. A flip-flop circuit comprising a master side element including a first data reading circuit and a first data retaining circuit, and a slave side element including a second data reading circuit and a second data retaining circuit,
wherein power supplies of the first data retaining circuit and the second data reading circuit are controlled by a normal phase clock signal input from an outside, and power supplies of the first data reading circuit and the second data retaining circuit are controlled by a reversed phase clock signal having a phase opposite to the normal phase clock signal, wherein the first data reading circuit includes a differential circuit, and wherein the first data retaining circuit, the second data reading circuit, and the second data retaining circuit include inverter circuits.

2. The flip-flop circuit according to claim 1, wherein the first data retaining circuit includes a first NMOS, and an input end and an output end of a first inverter are interconnected with an output end and an input end of a second inverter, wherein an earthing end of the first inverter and the second inverter is connected to a low potential side power supply via the first NMOS, and wherein a power supply end of the first inverter and the second inverter is connected to a high potential side power supply.

3. The flip-flop circuit according to claim 2, wherein the first data reading circuit includes a first PMOS, a second PMOS, a second NMOS, a third NMOS, and a fourth NMOS,
wherein an input end of the first inverter in the first data retaining circuit is connected to the high potential side power supply via the first PMOS, and is connected to the low potential side power supply via the second NMOS and the third NMOS,
and wherein an input end of the second inverter in the first data retaining circuit is connected to the high potential side power supply via the second PMOS, and is connected to the low potential side power supply via the fourth NMOS and the third NMOS.

4. The flip-flop circuit according to claim 3, wherein the second data retaining circuit includes a fifth NMOS, and an input end and an output end of a third inverter are interconnected with an output end and an input end of a fourth inverter, wherein an earthing end of the third inverter and the fourth inverter is connected to a low potential side power supply via the fifth NMOS, and wherein a power supply end of each of the third inverter and the fourth inverter is connected to the high potential side power supply.

5. The flip-flop circuit according to claim 4, wherein the second data reading circuit includes a third PMOS, a fourth PMOS, a sixth NMOS, a seventh NMOS, and a eighth NMOS,
wherein an input end of the third inverter in the second data retaining circuit is connected to the high potential side power supply via the fourth PMOS, and is connected to the low potential side power supply via the eighth NMOS and the seventh NMOS,
wherein an input end of the fourth inverter in the second data retaining circuit is connected to the high potential side power supply via the third PMOS, and is connected to the low potential side power supply via the sixth NMOS and the seventh NMOS,
wherein an output end of the first inverter, i.e., one of output ends of the master side element, is connected to a gate terminal of the eighth NMOS, i.e., one of input ends of the slave side element,
and wherein an output end of the second inverter, i.e., the other of output ends of the master side element, is connected to a gate terminal of the sixth NMOS, i.e., the other of input ends of the slave side element.

6. The flip-flop circuit according to claim 4, wherein the second data reading circuit includes a fifth inverter, a sixth inverter, and a seventh NMOS,
wherein an input end of the third inverter in the second data retaining circuit is connected to an output end of the fifth inverter, and an input end of the fourth inverter in the second data retaining circuit is connected to an output end of the sixth inverter,
and wherein an earthing end of each of the fifth inverter and the sixth inverter is connected to the low potential side power supply via the seventh NMOS, and a power supply end of the fifth inverter and the sixth inverter is connected to the high potential side power supply.

7. The flip-flop circuit according to claim 5, wherein the normal phase clock signal is input to a gate terminal of each of the first PMOS, the second PMOS, the first NMOS, and the seventh NMOS, and a reversed phase clock signal having a phase opposite to the normal phase clock signal is input to a gate terminal of each of the third PMOS, the fourth PMOS, the third NMOS, and the fifth NMOS.

8. The flip-flop circuit according to claim 6, wherein the normal phase clock signal is input to a gate terminal of each of the first PMOS, the second PMOS, the first NMOS, and the seventh NMOS, and a reversed phase clock signal having a phase opposite to the normal phase clock signal is input to a gate terminal of each of the third NMOS and the fifth NMOS.

9. The flip-flop circuit according to claim 7, wherein the input terminal for inputting the normal phase data signal is the gate terminal of the second NMOS, and the input terminal for inputting the reversed phase data signal having a phase opposite to the normal phase data signal is the gate terminal of the fourth NMOS,
and wherein in the output terminal of the flip-flop circuit, an output end of the third inverter is a normal phase output signal terminal for outputting the normal phase output signal, and an output end of the fourth inverter is a reversed phase output terminal for outputting the reversed phase output signal having a phase opposite to the normal phase output signal.

10. The flip-flop circuit according to claim 8, wherein the input terminal for inputting the normal phase data signal is the gate terminal of the second NMOS, and the input terminal for inputting the reversed phase data signal having a phase opposite to the normal phase data signal is the gate terminal of the fourth NMOS,
and wherein in the output terminal of the flip-flop circuit, an output end of the third inverter is a normal phase output signal terminal for outputting the normal phase output signal, and an output end of the fourth inverter is a reversed phase output terminal for outputting the reversed phase output signal having a phase opposite to the normal phase output signal.

11. The flip-flop circuit according to claim 7, wherein the master side element and the slave side element further comprising reset devices,
wherein the reset devices comprises:
a first reset circuit arranged between the high potential side power supply and the output end of the second inverter, i.e., the output end of the master side element;
a second reset circuit in which a drain terminal and a source terminal of the first NMOS are respectively connected to a drain terminal and a source terminal of the second reset circuit in first data retaining circuit;
a third reset circuit in which a drain terminal and a source terminal of the seventh NMOS are respectively connected to a drain terminal and a source terminal of the third reset circuit in second retaining circuit; and
a fourth reset circuit arranged between the high potential side power supply and an output end of the fourth inverter, i.e., an output signal terminal of the reversed phase of the flip-flop circuit,
wherein the normal phase reset signal is input to a control terminal of each of the second reset circuit and the third reset circuit, and the reversed phase reset signal having a phase opposite to the normal phase reset signal is input to a control terminal of each of the first reset circuit and the fourth reset circuit.

12. The flip-flop circuit according to claim 8, wherein the master side element and the slave side element further comprising reset devices,
wherein the reset devices comprises:
a first reset circuit arranged between the high potential side power supply and the output end of the second inverter, i.e., the output end of the master side element;
a second reset circuit in which a drain terminal and a source terminal of the first NMOS are respectively connected to a drain terminal and a source terminal of the second reset circuit in first data retaining circuit;
a third reset circuit in which a drain terminal and a source terminal of the seventh NMOS are respectively connected to a drain terminal and a source terminal of the third reset circuit in second retaining circuit; and
a fourth reset circuit arranged between the high potential side power supply and an output end of the fourth inverter, i.e., an output signal terminal of the reversed phase of the flip-flop circuit,
wherein the normal phase reset signal is input to a control terminal of each of the second reset circuit and the third reset circuit, and the reversed phase reset signal having a phase opposite to the normal phase reset signal is input to a control terminal of each of the first reset circuit and the fourth reset circuit.

13. The flip-flop circuit according to claim 7, wherein the first data reading circuit and the first data retaining circuit in the master side element and the second data reading circuit and the second data retaining circuit in the slave side element further include power-down devices for inputting a power-down signal for turning off a power supply,
wherein the power-down devices comprises:
a first power-down circuit arranged between the high potential side power supply and a source of each of the first PMOS and the second PMOS of the first data reading circuit in the master side element;
a second power-down circuit arranged between the high potential side power supply and a power supply end of the first inverter and the second inverter of first data retaining circuit in the master side element;
a third power-down circuit arranged between the high potential side power supply and a source of each of the third PMOS and the fourth PMOS of the second data reading circuit in the slave side element; and
a fourth power-down circuit arranged between the high potential side power supply and a power supply end of the third inverter and the fourth inverter of second data retaining circuit in the slave side element,
and wherein the power-down signal for turning off a power supply is configured to input to a control terminal of each of the first power-down circuit, the second power-down circuit, the third power-down circuit, and the fourth power-down circuit.

14. The flip-flop circuit according to claim 8, wherein the first data reading circuit and the first data retaining circuit in the master side element and the second data reading circuit and the second data retaining circuit in the slave side element further include power-down devices for inputting a power-down signal for turning off a power supply,
wherein the power-down devices comprises:
a first power-down circuit arranged between the high potential side power supply and a source of each of the first PMOS and the second PMOS of the first data reading circuit in the master side element;
a second power-down circuit arranged between the high potential side power supply and a power supply end of the first inverter and the second inverter of first data retaining circuit in the master side element;
a third power-down circuit arranged between the high potential side power supply and a source of each of the third PMOS and the fourth PMOS of the second data reading circuit in the slave side element; and
a fourth power-down circuit arranged between the high potential side power supply and a power supply end of the third inverter and the fourth inverter of second data retaining circuit in the slave side element,
and wherein the power-down signal for turning off a power supply is configured to input to a control terminal of each of the first power-down circuit, the second power-down circuit, the third power-down circuit, and the fourth power-down circuit.

15. A flip-flop circuit comprising a master side element including a first data reading circuit and a first data retaining circuit and a slave side element including a second data reading circuit and a second data retaining circuit,
wherein a power supply of the second data reading circuit is controlled by a normal phase clock signal input from an outside, and a power supply of the first data reading circuit is controlled by a reversed phase clock signal having a phase opposite to the normal phase clock signal, wherein the first data reading circuit includes a differential circuit, and wherein the first data retaining circuit, the second data reading circuit, and the second data retaining circuit include inverter circuits.

16. The flip-flop circuit according to claim 15, wherein the second data retaining circuit is configured such that an input end and an output end of a third inverter are interconnected with an output end and an input end of a fourth inverter, wherein an earthing end of the third inverter and the fourth inverter is connected to a low potential side power supply, and wherein a power supply end of the third inverter and the fourth inverter is connected to a high potential side power supply.

17. The flip-flop circuit according to claim 16, wherein the second data reading circuit includes a fifth inverter, a sixth inverter, and a seventh NMOS,
wherein an input end of the third inverter in the second data retaining circuit is connected to an output end of the fifth inverter, and an input end of the fourth inverter in the second data retaining circuit is connected to an output end of the sixth inverter,
and wherein an earthing end of each of the fifth inverter and the sixth inverter is connected to the low potential side power supply via the seventh NMOS, and a power supply end of each of the fifth inverter and the sixth inverter is connected to the high potential side power supply.

18. A frequency dividing circuit comprising a logical circuit and the flip-flop circuit according to claim 1.

19. A frequency dividing circuit comprising a logical circuit and the flip-flop circuit according to claim 2.

20. A frequency dividing circuit comprising a logical circuit and the flip-flop circuit according to claim 3.

21. A frequency dividing circuit comprising a logical circuit and the flip-flop circuit according to claim 4.

22. A frequency dividing circuit comprising a logical circuit and the flip-flop circuit according to claim 5.

23. A frequency dividing circuit comprising a logical circuit and the flip-flop circuit according to claim 6.

24. A frequency dividing circuit comprising a logical circuit and the flip-flop circuit according to claim 7.

25. A frequency dividing circuit comprising a logical circuit and the flip-flop circuit according to claim 8.

26. A frequency dividing circuit comprising a logical circuit and the flip-flop circuit according to claim 9.

27. A frequency dividing circuit comprising a logical circuit and the flip-flop circuit according to claim 10.

28. A frequency dividing circuit comprising a logical circuit and the flip-flop circuit according to claim 11.

29. A frequency dividing circuit comprising a logical circuit and the flip-flop circuit according to claim 12.

30. A frequency dividing circuit comprising a logical circuit and the flip-flop circuit according to claim 13.

31. A frequency dividing circuit comprising a logical circuit and the flip-flop circuit according to claim 14.

32. A frequency dividing circuit comprising a logical circuit and the flip-flop circuit according to claim 15.

33. A frequency dividing circuit comprising a logical circuit and the flip-flop circuit according to claim 16.
